(19) United States
(12) Patent Application Publication
(10) Pub. No.: US 2025/0239506 A1
(43) Pub. Date: Jul. 24, 2025

(54) SEMICONDUCTOR MODULE

(71) Applicant: Rohm Co., Ltd., Kyoto-shi (JP)

(72) Inventor: Natsuya YOSHIDA, Kyoto-shi (JP)

(21) Appl. No.: 19/174,378

(22) Filed: Apr. 9, 2025

Related U.S. Application Data
(63) Continuation of application No. PCT/JP2023/041293, filed on Nov. 16, 2023.

(30) Foreign Application Priority Data
Nov. 29, 2022 (JP) 2022-189770

(51) Int. Cl. H01L 23/495; H01L 23/10; H01L 23/367

(52) U.S. Cl. CPC H01L 23/49568; H01L 23/10; H01L 23/3677; H01L 23/49548

(57) ABSTRACT

A semiconductor module includes: a heat dissipation member; a semiconductor device bonded to the heat dissipation member; and a covering layer that covers a part of the heat dissipation member, and that is an insulator. The semiconductor device includes a substrate located on one side of the heat dissipation member in a first direction and bonded to the heat dissipation member, a first conductive layer, a semiconductor element (a first element), a sealing resin, and a first power terminal that is electrically connected to the first conductive layer and the semiconductor element, and that includes a portion protruding from the sealing resin to an outside in a direction perpendicular to the first direction. The covering layer is located on the one side of the heat dissipation member in the first direction. As viewed in the first direction, the first power terminal overlaps with the heat dissipation member and the covering layer.

### TECHNICAL FIELD

The present disclosure relates to a semiconductor module provided with a heat dissipation member and a semiconductor device.

### BACKGROUND ART

WO 2017/094370 discloses an example of a semiconductor device provided with a heat dissipation member. The heat dissipation member includes a housing having a hollow region, and a radiator. The housing has an opening leading to the hollow region. The radiator is attached to the housing to close the opening. The radiator is partially housed in the hollow region. The semiconductor device is bonded to a portion of the radiator protruding outside the hollow region via a bonding material. When a coolant (e.g., cooling water) is poured into the hollow region, the coolant makes contact with the radiator. This allows cooling of the semiconductor device via the radiator.

The semiconductor device provided with the heat dissipation member in WO 2017/094370 includes P, O, and N terminals that each include a portion protruding outside from a sealing resin. The P terminal and the N terminal are supplied with DC power from outside. The O terminal outputs AC power obtained as a result of the conversion of the DC power by the semiconductor device. The creepage distance from each of the P, O, and N terminals to the radiator can be relatively short. Thus, there is a concern that the radiator may cause a decrease in the dielectric strength of the semiconductor device.

### BRIEF DESCRIPTION OF THE DRAWINGS

FIG. 1 is a perspective view showing a semiconductor module according to a first embodiment of the present disclosure.

FIG. 2 is a plan view showing the semiconductor module in FIG. 1.

FIG. 3 is a right-side view showing the semiconductor module in FIG. 1.

FIG. 4 is a cross-sectional view along line IV-IV in FIG. 2.

FIG. 5 is a cross-sectional view along line V-V in FIG. 2.

FIG. 6 is a partially enlarged view of FIG. 4.

FIG. 7 is a partially enlarged view of FIG. 5.

FIG. 8 is a plan view showing a semiconductor device in the semiconductor module in FIG. 1.

FIG. 9 is a plan view corresponding to FIG. 8, except that a sealing resin is shown as transparent.

FIG. 10 is a partially enlarged view of FIG. 9.

FIG. 11 is a plan view corresponding to FIG. 8, except that a first conductive member is shown as transparent and that the sealing resin and a second conductive member are omitted.

FIG. 12 is a right-side view showing the semiconductor device in FIG. 8.

FIG. 13 is a bottom view showing the semiconductor device in FIG. 8.

FIG. 14 is a cross-sectional view along line XIV-XIV in FIG. 9.

FIG. 15 is a cross-sectional view along line XV-XV in FIG. 9.

FIG. 16 is a partially enlarged view showing a first element and an area around the first element in FIG. 15.

FIG. 17 is a partially enlarged view showing a second element and an area around the second element in FIG. 15.

FIG. 18 is a cross-sectional view along line XVIII-XVIII in FIG. 9.

FIG. 19 is a cross-sectional view along line XIX-XIX in FIG. 9.

FIG. 20 is a plan view showing a semiconductor module according to a second embodiment of the present disclosure.

FIG. 21 is a cross-sectional view along line XXI-XXI in FIG. 20.

FIG. 22 is a cross-sectional view along line XXII-XXII in FIG. 20.

FIG. 23 is a partially enlarged view of FIG. 21.

FIG. 24 is a plan view showing a semiconductor module according to a third embodiment of the present disclosure.

FIG. 25 is a cross-sectional view along line XXV-XXV in FIG. 24.

FIG. 26 is a cross-sectional view along line XXVI-XXVI in FIG. 24.

FIG. 27 is a partially enlarged view of FIG. 25.

FIG. 28 is a plan view showing a semiconductor module according to a fourth embodiment of the present disclosure.

FIG. 29 is a cross-sectional view along line XXIX-XXIX in FIG. 28.

FIG. 30 is a plan view showing a semiconductor module according to a fifth embodiment of the present disclosure.

FIG. 31 is a cross-sectional view along line XXXI-XXXI in FIG. 30.

FIG. 32 is a cross-sectional view along line XXXII-XXXII in FIG. 30.

### DETAILED DESCRIPTION OF EMBODIMENTS

The following describes embodiments of the present disclosure with reference to the accompanying drawings.

### First Embodiment

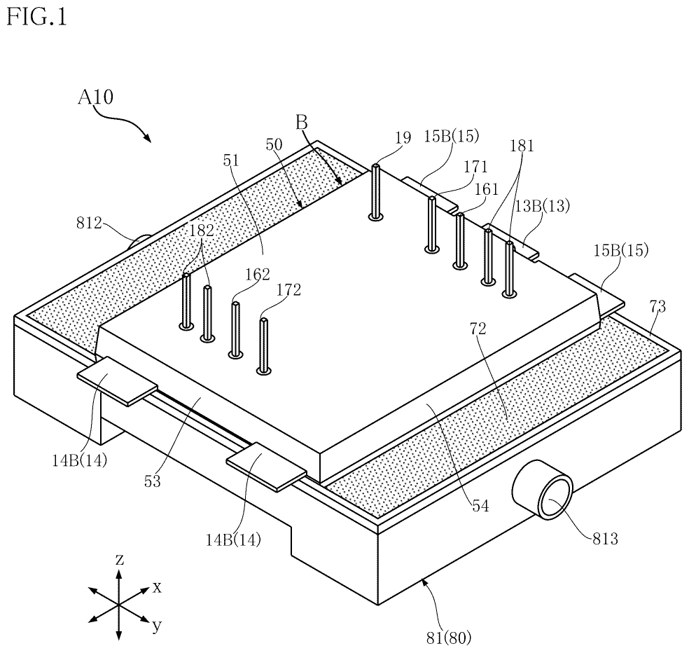

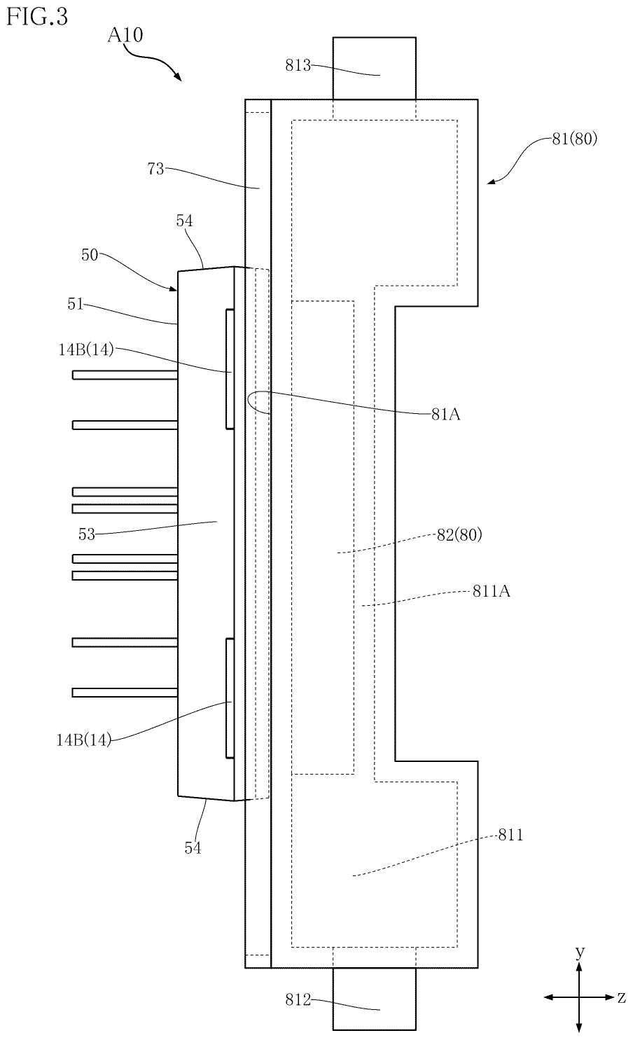

With reference to FIGS. 1 to 19, a semiconductor module A10 according to a first embodiment of the present disclosure will be described. The semiconductor module A10 may include a semiconductor device B, a bonding layer 71, a covering layer 72, a frame 73, and a heat dissipation member 80.

In the description of the semiconductor module A10, the direction normal to a first obverse surface 121A of a first conductive layer 121 (described below) of the semiconductor device B is defined as a “first direction z”. A direction perpendicular to the first direction z is defined as a “second direction x”. The direction perpendicular to both of the first direction z and the second direction x is defined as a “third direction y”.

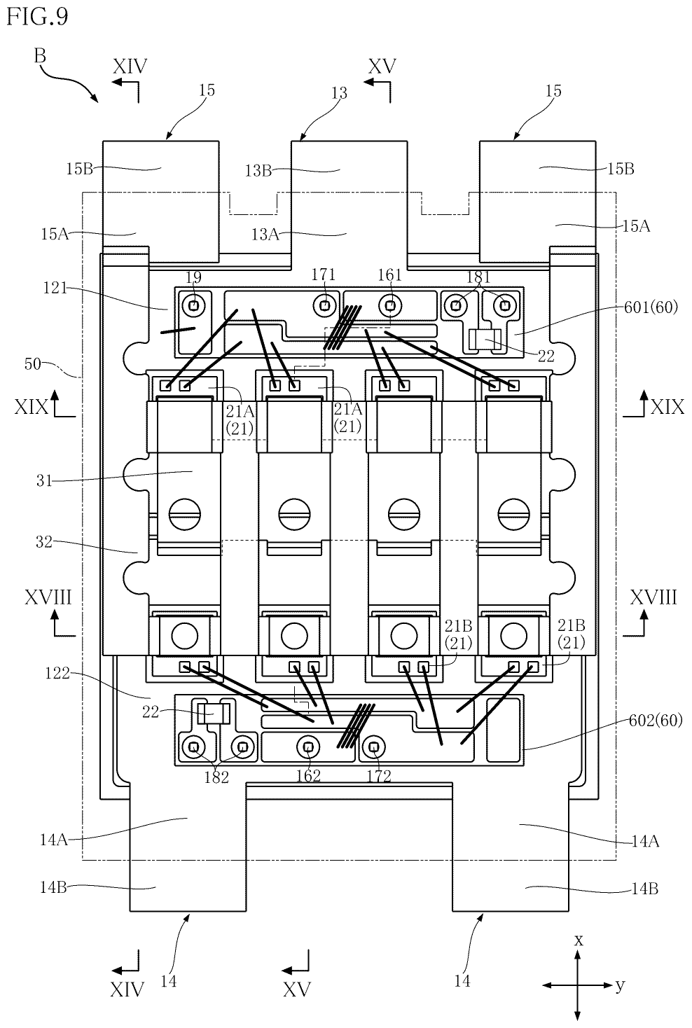

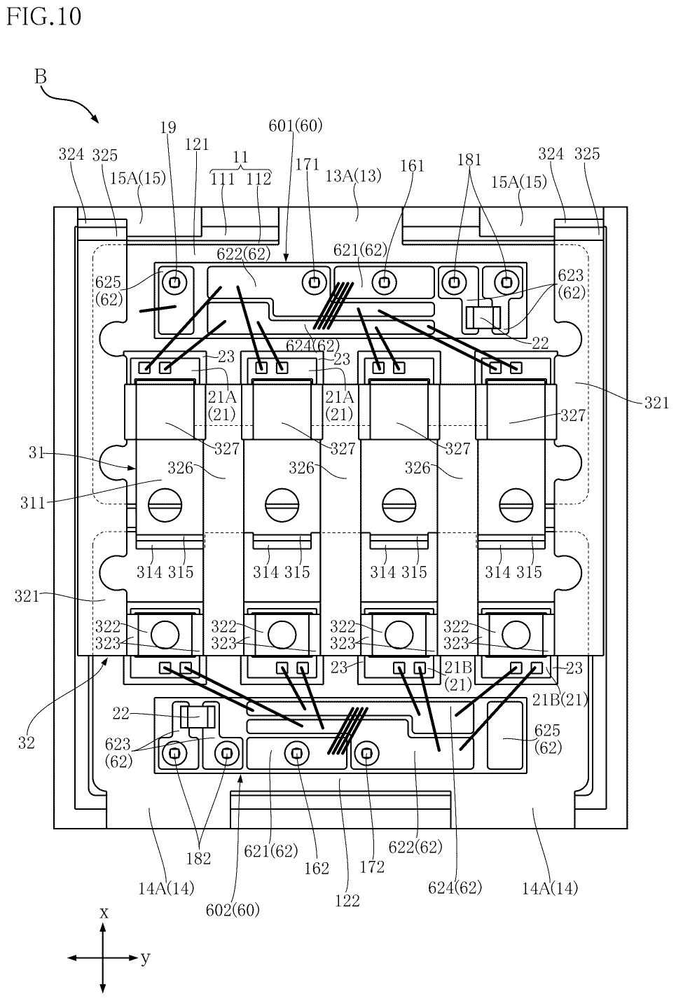

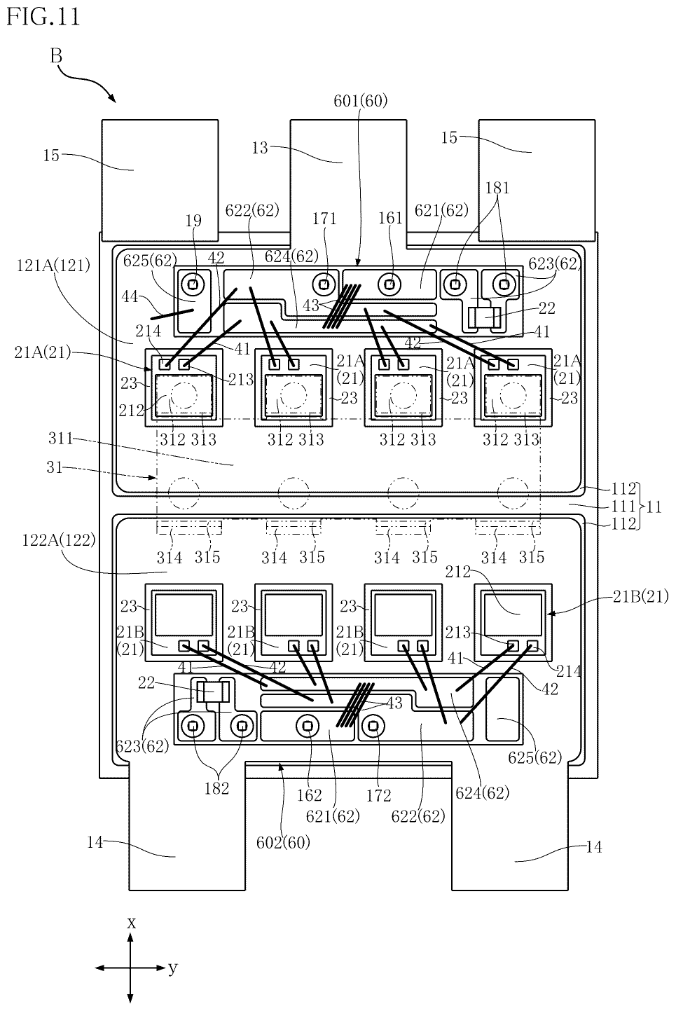

First, the semiconductor device B in the semiconductor module A10 will be described with reference to FIGS. 1, and 8 to 19. The semiconductor device B may include a substrate 11, a first conductive layer 121, a second conductive layer 122, a first power terminal 13, a second power terminal 14, a third power terminal 15, a first signal terminal 161, a second signal terminal 162, a plurality of semiconductor elements 20, a first conductive member 31, a second conductive member 32, and a sealing resin 50. The semiconductor device B may include a third signal terminal 171, a fourth signal terminal 172, a pair of fifth signal terminals 181, a pair of sixth signal terminals 182, a seventh signal terminal 19, a pair of thermistors 22, and a pair of control wirings 60. For the convenience of illustration, FIGS. 9 and 10 show the sealing resin 50 as transparent. In FIG. 9, the outline of the sealing resin 50 is indicated by imaginary lines (two-dot-dash lines). For the convenience of illustration, FIG. 11 shows the first conductive member 31 as transparent and omits the second conductive member 32 and the sealing resin 50. In FIG. 11, the outline of the first conductive member 31 is indicated by imaginary lines. FIG. 9 also shows line XV-XV with dot-dash lines.

The semiconductor device B may be configured to convert DC source voltage applied to the first power terminal 13 and the third power terminal 15 into AC power using the semiconductor elements 21. The resulting AC power may be outputted from the second power terminal 14 to a power supply target, such as a motor.

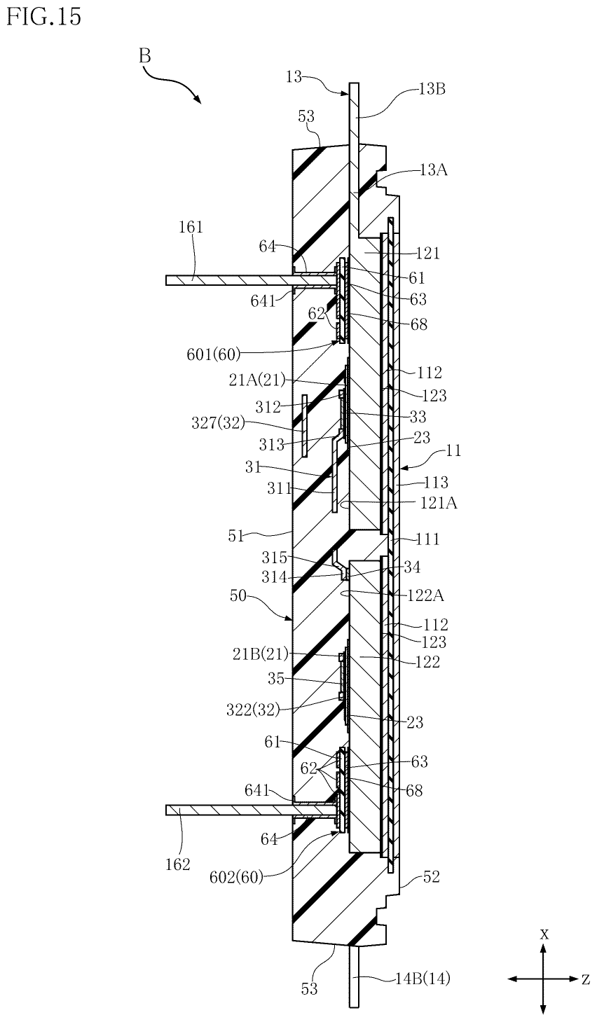

As shown in FIGS. 15 to 17, the substrate 11 may be located opposite to the semiconductor elements 21 with the first conductive layer 121 and the second conductive layer 122 interposed therebetween in the first direction z. The substrate 11 may support the first conductive layer 121 and the second conductive layer 122. In the semiconductor device B, the substrate 11 may be made of a direct bonded copper (DBC) substrate. As shown in FIGS. 15 to 17, the substrate 11 may include an insulating layer 111, a pair of metal layers 112, and a heat dissipation layer 113. The substrate 11 may be covered with the sealing resin 50 except for a part of the heat dissipation layer 113.

As shown in FIGS. 15 to 17, the insulating layer 111 may include a portion interposed between the metal layers 112 and the heat dissipation layer 113 in the first direction z. The insulating layer 111 may be made of a material having a relatively high thermal conductivity. The insulating layer 111 may be made of ceramic containing sintered aluminum nitride (AlN), for example. The insulating layer 111 may be made of a sheet of insulating resin instead of ceramic. The thickness of the insulating layer 111 may be smaller than the thickness of each of the first conductive layer 121 and the second conductive layer 122.

As shown in FIGS. 15 to 17, each of the metal layers 112 may be located between the insulating layer 111 and one of the first conductive layer 121 and the second conductive layer 122 in the first direction z. The composition of the pair of metal layers 112 may include copper (Cu). As shown in FIG. 11, each of the pair of metal layers 112 may be surrounded by the periphery of the insulating layer 111 as viewed in the first direction z.

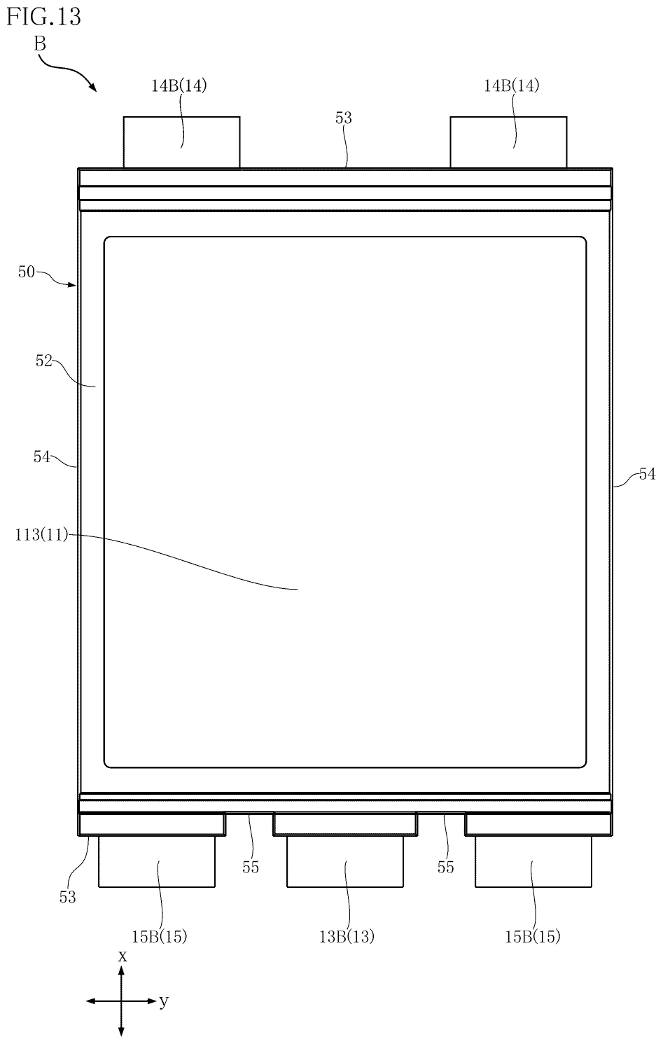

As shown in FIGS. 15 to 17, the heat dissipation layer 113 may be located opposite to the metal layers 112 with the insulating layer 111 interposed therebetween in the first direction z. As shown in FIG. 13, the heat dissipation layer 113 may be exposed from the sealing resin 50. The composition of the heat dissipation layer 113 may include copper. The thickness of the heat dissipation layer 113 may be greater than that of the insulating layer 111. As viewed in the first direction z, the heat dissipation layer 113 may be surrounded by the periphery of the insulating layer 111.

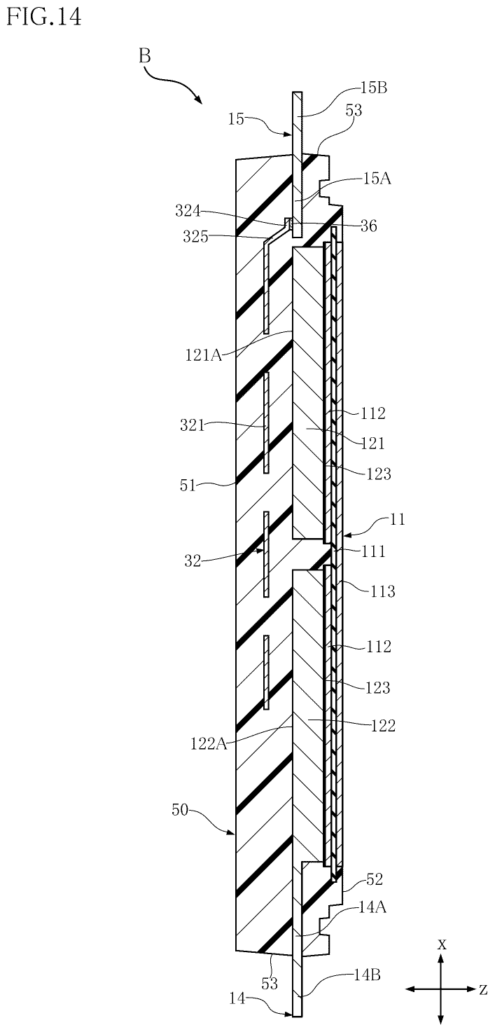

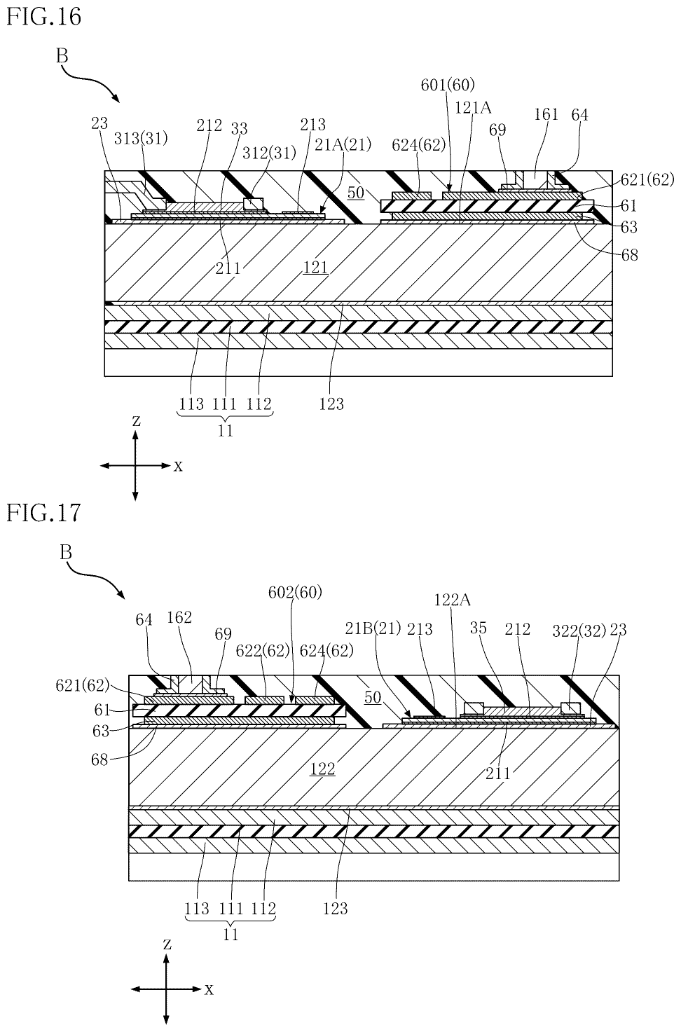

As shown in FIGS. 15 to 17, the first conductive layer 121 and the second conductive layer 122 may be bonded to the substrate 11. The composition of each of the first conductive layer 121 and the second conductive layer 122 may include copper. The first conductive layer 121 and the second conductive layer 122 may be spaced apart from each other in the second direction x. As shown in FIGS. 14 and 15, the first conductive layer 121 may have a first obverse surface 121A facing in the first direction z. The first obverse surface 121A faces the semiconductor elements 21. As shown in FIG. 16, the first conductive layer 121 may be bonded to one of the pair of metal layers 112 via a bonding layer 123. The bonding layer 123 may be a brazing material containing silver (Ag), for example. As shown in FIGS. 14 and 15, the second conductive layer 122 may have a second obverse surface 122A facing in the first direction z. The second obverse surface 122A may face the same side as the first obverse surface 121A in the first direction z. As shown in FIG. 17, the second conductive layer 122 may be bonded to the other one of the pair of metal layers 112 via the bonding layer 123. The dimension of each of the first conductive layer 121 and the second conductive layer 122 in the first direction z may be greater than that of the substrate 11 in the first direction z.

As shown in FIGS. 11 and 15, each of the semiconductor elements 21 may be mounted on one of the first conductive layer 121 and the second conductive layer 122. The semiconductor elements 21 may be metal-oxide-semiconductor field-effect transistors (MOSFETs). Alternatively, the semiconductor elements 21 may be switching elements, such as insulated gate bipolar transistors (IGBTs), or diodes. In the description of the semiconductor device B, the semiconductor elements 21 may be n-channel MOSFETs each having a vertical structure. Each of the semiconductor elements 21 may include a compound semiconductor substrate. The composition of the compound semiconductor substrate may include silicon carbide (SiC).

As shown in FIG. 11, the semiconductor elements 21 of the semiconductor device B may include a plurality of first elements 21A and a plurality of second elements 21B. Each second element 21B may have the same structure as each first element 21A. The first elements 21A may be mounted on the first obverse surface 121A of the first conductive layer 121. The first elements 21A may be aligned in the third direction y. The second elements 21B may be mounted on the second obverse surface 122A of the second conductive layer 122. The second elements 21B may be aligned in the third direction y.

As shown in FIGS. 11, 16, and 17, each of the semiconductor elements 21 may have a first electrode 211, a second electrode 212, a third electrode 213, and a fourth electrode 214.

As shown in FIGS. 16 and 17, the first electrode 211 may face one of the first conductive layer 121 and the second conductive layer 122. The first electrode 211 may pass the current corresponding to the power before conversion by the semiconductor element 21. In other words, the first electrode 211 may correspond to the drain electrode of the semiconductor element 21.

As shown in FIGS. 16 and 17, the second electrode 212 may be located opposite to the first electrode 211 in the first direction z. The second electrode 212 may pass the current corresponding to the power obtained as a result of the conversion by the semiconductor element 21. In other words, the second electrode 212 may correspond to the source electrode of the semiconductor element 21.

As shown in FIGS. 16 and 17, the third electrode 213 may be located on the same side as the second electrode 212 in the first direction z. A gate voltage for driving the semiconductor element 21 may be applied to the third electrode 213. In other words, the third electrode 213 may correspond to the gate electrode of the semiconductor element 21. As shown in FIG. 11, the area of the third electrode 213 may be smaller than the area of the second electrode 212 as viewed in the first direction z.

As shown in FIG. 11, the fourth electrode 214 is located on the same side as the second electrode 212 in the first direction z, and is adjacent to the third electrode 213 in the third direction y. The potential of the fourth electrode 214 may be equal to the potential of the second electrode 212.

As shown in FIGS. 16 and 17, conductive bonding layers 23 may be each interposed between one of the first conductive layer 121 and the second conductive layer 122 and the first electrode 211 of one of the semiconductor elements 21. The conductive bonding layers 23 may be solder. Alternatively, the conductive bonding layers 23 may contain sintered metal particles. The first electrodes 211 of the first elements 21A may be electrically bonded to the first obverse surface 121A of the first conductive layer 121 via the relevant conductive bonding layers 23. Thus, the first electrodes 211 of the first elements 21A may be electrically connected to the first conductive layer 121. The first electrodes 211 of the second elements 21B may be electrically bonded to the second obverse surface 122A of the second conductive layer 122 via the relevant conductive bonding layers 23. Thus, the first electrodes 211 of the second elements 21B may be electrically connected to the second conductive layer 122.

As shown in FIGS. 9 and 15, the first power terminal 13 may be located opposite to the second conductive layer 122 with the first conductive layer 121 interposed therebetween in the second direction x, and may be connected to the first conductive layer 121. Thus, the first power terminal 13 may be electrically connected to the first electrodes 211 of the first elements 21A via the first conductive layer 121. The first power terminal 13 may be a P terminal (positive electrode) to which the DC source voltage targeted for power conversion is applied. The first power terminal 13 may extend from the first conductive layer 121 in the second direction x. The first power terminal 13 may have a covered portion 13A and an exposed portion 13B. As shown in FIG. 15, the covered portion 13A may be connected to the first conductive layer 121 and covered with the sealing resin 50. The covered portion 13A may be flush with the first obverse surface 121A of the first conductive layer 121. The exposed portion 13B may extend from the covered portion 13A in the second direction x, and may be exposed from the sealing resin 50.

As shown in FIGS. 9 and 14, the second power terminal 14 may be located opposite to the first conductive layer 121 with the second conductive layer 122 interposed therebetween in the second direction x, and may be connected to the second conductive layer 122. Thus, the second power terminal 14 may be electrically connected to the first electrodes 211 of the second elements 21B via the second conductive layer 122. The second power terminal 14 may output the AC power obtained as a result of the conversion by the semiconductor element 21. In the semiconductor device B, the second power terminal 14 may include a pair of regions spaced apart from each other in the third direction y. Alternatively, the second power terminal 14 may be a single component not including the pair of regions. The second power terminal 14 may have a covered portion 14A and an exposed portion 14B. As shown in FIG. 14, the covered portion 14A may be connected to the second conductive layer 122 and covered with the sealing resin 50. The covered portion 14A may be flush with the second obverse surface 122A of the second conductive layer 122. The exposed portion 14B may extend from the covered portion 14A in the second direction x, and may be exposed from the sealing resin 50.

As shown in FIGS. 9 and 14, the third power terminal 15 may be located on the same side as the first power terminal 13 with respect to the first conductive layer 121 and the second conductive layer 122 in the second direction x, and may be spaced apart from the first conductive layer 121 and the second conductive layer 122. The third power terminal 15 may be electrically connected to the second electrodes 212 of the second elements 21B. The third power terminal 15 may be an N terminal (negative electrode) to which the DC source voltage targeted for power conversion is applied. The third power terminal 15 may include a pair of regions spaced apart from each other in the third direction y. The first power terminal 13 may be located between the pair of regions in the third direction y. The third power terminal 15 may have a covered portion 15A and an exposed portion 15B. As shown in FIG. 14, the covered portion 15A may be spaced apart from the first conductive layer 121 and covered with the sealing resin 50. The exposed portion 15B may extend from the covered portion 15A in the second direction x, and may be exposed from the sealing resin 50.

The pair of control wirings 60 may form parts of conductive paths connecting the first signal terminal 161, the second signal terminal 162, the third signal terminal 171, the fourth signal terminal 172, the pair of fifth signal terminals 181, and the pair of sixth signal terminals 182 to the semiconductor elements 21. As shown in FIGS. 9 to 11, the pair of control wirings 60 may include a first wiring 601 and a second wiring 602. The first wiring 601 may be located between the first elements 21A and the first and third power terminals 13 and 15. The first wiring 601 may be bonded to the first obverse surface 121A of the first conductive layer 121. The first wiring 601 may also form a part of the conductive path between the seventh signal terminal 19 and the first conductive layer 121. The second wiring 602 may be located between the second elements 21B and the second power terminal 14 in the second direction x. The second wiring 602 may be bonded to the second obverse surface 122A of the second conductive layer 122. As shown in FIGS. 16 and 17, each of the pair of control wirings 60 may include an insulating layer 61, a plurality of wiring layers 62, a metal layer 63, and a plurality of sleeves 64. The pair of control wirings 60 may be covered with the sealing resin 50 except for parts of the sleeves 64.

As shown in FIGS. 16 and 17, the insulating layer 61 may include portions interposed between the wiring layers 62 and the metal layer 63 in the first direction z. The insulating layer 61 may be made of ceramic, for example. The insulating layer 61 may be made of a sheet of insulating resin rather than ceramic.

As shown in FIGS. 16 and 17, the wiring layers 62 may be located on a side of the insulating layer 61 in the first direction z. The composition of the wiring layers 62 may include copper. As shown in FIG. 11, each of the wiring layers 62 may include a first wiring layer 621, a second wiring layer 622, a pair of third wiring layers 623, a fourth wiring layer 624, and a fifth wiring layer 625. The pair of third wiring layers 623 may be adjacent to each other in the third direction y.

As shown in FIGS. 16 and 17, the metal layer 63 may be located opposite to the wiring layers 62 with the insulating layer 61 interposed therebetween in the first direction z. The composition of the metal layer 63 may include copper. The metal layer 63 of the first wiring 601 may be bonded to the first obverse surface 121A of the first conductive layer 121 via a first adhesive layer 68. The metal layer 63 of the second wiring 602 may be bonded to the second obverse surface 122A of the second conductive layer 122 via a first adhesive layer 68. The first adhesive layers 68 may be made of a conductive or a non-conductive material. The first adhesive layers 68 may be made of solder.

As shown in FIGS. 16 and 17, each of the sleeves 64 may be bonded to one of the wiring layers 62 by a second adhesive layer 69. The sleeves 64 may be made of a conductive material such as metal. Each of the sleeves 64 may have a tubular shape extending in the first direction z.

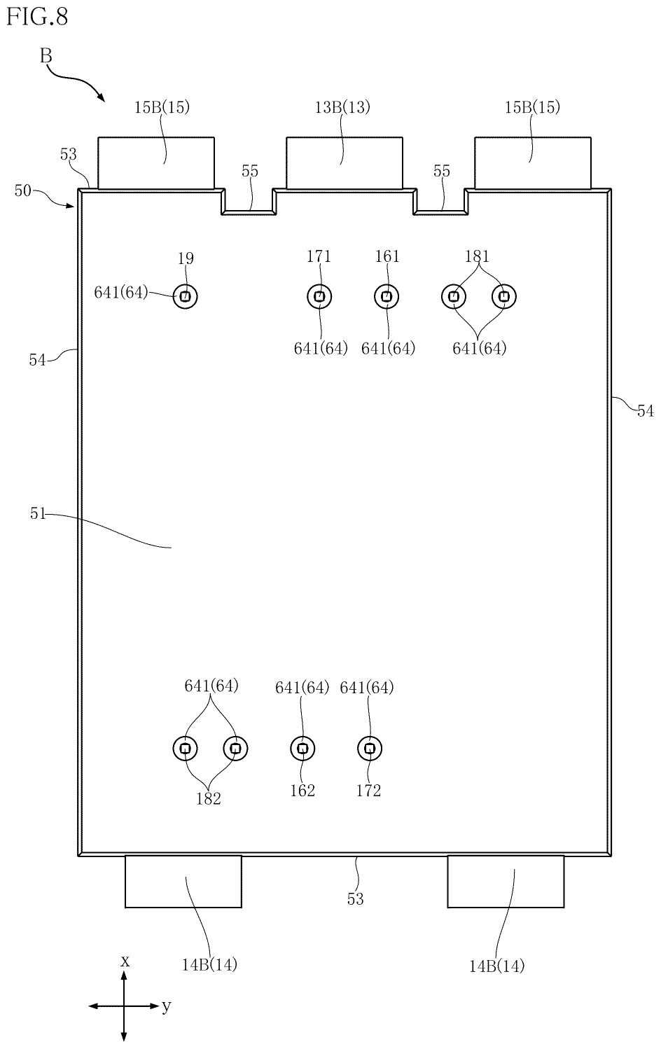

An end of each sleeve 64 may be electrically bonded to one of the wiring layers 62. As shown in FIGS. 8 and 15, the other end of each sleeve 64 may have an end surface 641 exposed from a top surface 51 (described below) of the sealing resin 50. The second adhesive layers 69 may be electrically conductive. The second adhesive layers 69 may be made of solder.

As shown in FIG. 10, one of the pair of thermistors 22 may be electrically bonded to the pair of third wiring layers 623 of the first wiring 601. As shown in FIG. 10, the other one of the pair of thermistors 22 may be electrically bonded to the pair of third wiring layers 623 of the second wiring 602. The pair of thermistors 22 may be negative temperature coefficient (NTC) thermistors, for example. The NTC thermistors may have a characteristic that the resistance decreases gradually as the temperature rises. The pair of thermistors 22 may be used as temperature detection sensors for the semiconductor device B.

The first signal terminal 161, the second signal terminal 162, the third signal terminal 171, the fourth signal terminal 172, the pair of fifth signal terminals 181, the pair of sixth signal terminals 182, and the seventh signal terminal 19 may be metal pins extending in the first direction z, as shown in FIG. 1. These terminals may protrude from the top surface 51 (described below) of the sealing resin 50. These terminals may be pressed into the respective sleeves 64 of the pair of control wirings 60. Thus, each of these terminals may be supported by one of the sleeves 64 and electrically connected to one of the wiring layers 62.

As shown in FIGS. 11 and 16, the first signal terminal 161 may be pressed into the sleeve 64 bonded to the first wiring layer 621 of the first wiring 601 among the sleeves 64 of the pair of control wirings 60. Thus, the first signal terminal 161 may be supported by the sleeve 64 and electrically connected to the first wiring layer 621 of the first wiring 601. The first signal terminal 161 may also be electrically connected to the third electrodes 213 of the first elements 21A. A gate voltage for driving the first elements 21A may be applied to the first signal terminal 161.

As shown in FIGS. 11 and 17, the second signal terminal 162 may be pressed into the sleeve 64 bonded to the first wiring layer 621 of the second wiring 602 among the sleeves 64 of the pair of control wirings 60. Thus, the second signal terminal 162 may be supported by the sleeve 64 and electrically connected to the first wiring layer 621 of the second wiring 602. The second signal terminal 162 may also be electrically connected to the third electrodes 213 of the second elements 21B. A gate voltage for driving the second elements 21B may be applied to the second signal terminal 162.

As shown in FIG. 8, the third signal terminal 171 may be located adjacent to the first signal terminal 161 in the third direction y. As shown in FIG. 11, the third signal terminal 171 may be pressed into the sleeve 64 bonded to the second wiring layer 622 of the first wiring 601 among the sleeves 64 of the pair of control wirings 60. Thus, the third signal terminal 171 may be supported by the sleeve 64 and electrically connected to the second wiring layer 622 of the first wiring 601. The third signal terminal 171 may also be electrically connected to the fourth electrodes 214 of the first elements 21A. A voltage corresponding to the current that is the largest of the currents flowing through the fourth electrodes 214 of the first elements 21A may be applied to the third signal terminal 171.

As shown in FIG. 8, the fourth signal terminal 172 may be located adjacent to the second signal terminal 162 in the third direction y. As shown in FIG. 11, the fourth signal terminal 172 may be pressed into the sleeve 64 bonded to the second wiring layer 622 of the second wiring 602 among the sleeves 64 of the pair of control wirings 60. Thus, the fourth signal terminal 172 may be supported by the sleeve 64 and electrically connected to the second wiring layer 622 of the second wiring 602. The fourth signal terminal 172 may also be electrically connected to the fourth electrodes 214 of the second elements 21B. A voltage corresponding to the current that is the largest of the currents flowing through the fourth electrodes 214 of the second elements 21B may be applied to the fourth signal terminal 172.

As shown in FIG. 8, the pair of fifth signal terminals 181 may be located opposite to the third signal terminal 171 with the first signal terminal 161 interposed therebetween in the third direction y. The pair of fifth signal terminals 181 may be adjacent to each other in the third direction y. As shown in FIG. 11, the pair of fifth signal terminals 181 may be respectively pressed into the pair of sleeves 64 bonded to the pair of third wiring layers 623 of the first wiring 601 among the sleeves 64 of the pair of control wirings 60. Thus, the pair of fifth signal terminals 181 may be supported by the pair of sleeves 64 and electrically connected to the pair of third wiring layers 623 of the first wiring 601. The pair of fifth signal terminals 181 may also be electrically connected to the thermistor 22 electrically bonded to the pair of third wiring layers 623 of the first wiring 601.

As shown in FIG. 8, the pair of sixth signal terminals 182 may be located opposite to the fourth signal terminal 172 with the second signal terminal 162 interposed therebetween in the third direction y. The pair of sixth signal terminals 182 may be adjacent to each other in the third direction y. As shown in FIG. 11, the pair of sixth signal terminals 182 may be respectively pressed into the pair of sleeves 64 bonded to the pair of third wiring layers 623 of the second wiring 602 among the sleeves 64 of the pair of control wirings 60. Thus, the pair of sixth signal terminals 182 may be supported by the pair of sleeves 64 and electrically connected to the pair of third wiring layers 623 of the second wiring 602. The pair of sixth signal terminals 182 may also be electrically connected to the thermistor 22 electrically bonded to the third wiring layers 623 of the second wiring 602.

As shown in FIG. 8, the seventh signal terminal 19 may be located opposite to the first signal terminal 161 with the third signal terminal 171 interposed therebetween in the third direction y. As shown in FIG. 11, the seventh signal terminal 19 may be pressed into the sleeve 64 bonded to the fifth wiring layer 625 of the first wiring 601 among the sleeves 64 of the pair of control wirings 60. Thus, the seventh signal terminal 19 may be supported by the sleeve 64 and electrically connected to the fifth wiring layer 625 of the first wiring 601. The seventh signal terminal 19 may also be electrically connected to the first conductive layer 121. A voltage corresponding to the DC power inputted to the first power terminal 13 and the third power terminal 15 may be applied to the seventh signal terminal 19.

As shown in FIG. 11, a plurality of first wires 41 may be electrically bonded to the third electrodes 213 of the first elements 21A and the fourth wiring layer 624 of the first wiring 601. As shown in FIG. 11, a plurality of third wires 43 may be electrically bonded to the fourth wiring layer 624 of the first wiring 601 and the first wiring layer 621 of the first wiring 601. Thus, the first signal terminal 161 may be electrically connected to the third electrodes 213 of the first elements 21A. The composition of the first wires 41 and the third wires 43 may include gold (Au). Alternatively, the composition of the first wires 41 and the third wires 43 may include copper or aluminum (Al).

As shown in FIG. 11, a plurality of first wires 41 may be electrically bonded to the third electrodes 213 of the second elements 21B and the fourth wiring layer 624 of the second wiring 602. As shown in FIG. 11, a plurality of third wires 43 may be electrically bonded to the fourth wiring layer 624 of the second wiring 602 and the first wiring layer 621 of the second wiring 602. Thus, the second signal terminal 162 may be electrically connected to the third electrodes 213 of the second elements 21B.

As shown in FIG. 11, a plurality of second wires 42 may be electrically bonded to the fourth electrodes 214 of the first elements 21A and the second wiring layer 622 of the first wiring 601. Thus, the third signal terminal 171 may be electrically connected to the fourth electrodes 214 of the first elements 21A. As shown in FIG. 11, a plurality of second wires 42 may be electrically bonded to the fourth electrodes 214 of the second elements 21B and the second wiring layer 622 of the second wiring 602. Thus, the fourth signal terminal 172 may be electrically connected to the fourth electrodes 214 of the second elements 21B. The composition of the second wires 42 may include gold. Alternatively, the composition of the second wires 42 may include copper or aluminum.

As shown in FIG. 11, a fourth wire 44 may be electrically bonded to the fifth wiring layer 625 of the first wiring 601 and the first obverse surface 121A of the first conductive layer 121. Thus, the seventh signal terminal 19 may be electrically connected to the first conductive layer 121. The composition of the fourth wire 44 may include gold. Alternatively, the composition of the fourth wire 44 may include copper or aluminum.

As shown in FIGS. 11 and 16, the first conductive member 31 may be electrically bonded to the second electrodes 212 of the first elements 21A and the second obverse surface 122A of the second conductive layer 122. Thus, the second electrodes 212 of the first elements 21A may be electrically connected to the second conductive layer 122. The composition of the first conductive member 31 may include copper. The first conductive member 31 may be a metal clip. As shown in FIG. 11, the first conductive member 31 may have a main body 311, a plurality of first bond portions 312, a plurality of first connecting portions 313, a second bond portion 314, and a second connecting portion 315.

The main body 311 may be the main part of the first conductive member 31. As shown in FIG. 11, the main body 311 extends in the third direction y. As shown in FIG. 15, the main body 311 bridges the gap between the first conductive layer 121 and the second conductive layer 122.

As shown in FIG. 16, the first bond portions 312 may be bonded to the second electrodes 212 of the respective first elements 21A. Each of the first bond portions 312 faces the second electrode 212 of one of the first elements 21A.

As shown in FIG. 11, the first connecting portions 313 may be connected to the main body 311 and the first bond portions 312. The first connecting portions 313 may be spaced apart from each other in the third direction y. As shown in FIG. 15, as viewed in the third direction y, the first connecting portions 313 may be inclined to be farther away from the first obverse surface 121A of the first conductive layer 121 as proceeding from the first bond portions 312 toward the main body 311.

As shown in FIGS. 11 and 15, the second bond portion 314 may be bonded to the second obverse surface 122A of the second conductive layer 122. The second bond portion 314 may face the second obverse surface 122A. The second bond portion 314 may extend in the third direction y. The dimension of the second bond portion 314 in the third direction y may be equal to the dimension of the main body 311 in the third direction y.

As shown in FIGS. 11 and 15, the second connecting portion 315 may be connected to the main body 311 and the second bond portion 314. As viewed in the third direction y, the second connecting portion 315 may be inclined to be farther away from the second obverse surface 122A of the second conductive layer 122 as proceeding from the second bond portion 314 toward the main body 311. The dimension of the second connecting portion 315 in the third direction y may be equal to the dimension of the main body 311 in the third direction y.

As shown in FIGS. 15, 16, and 19, the semiconductor device B may further include first conductive bonding layers 33. The first conductive bonding layers 33 may be interposed between the second electrodes 212 of the first elements 21A and the first bond portions 312. The first conductive bonding layers 33 may electrically bond the second electrodes 212 of the first elements 21A and the first bond portions 312. The first conductive bonding layers 33 may be solder, for example. Alternatively, the first conductive bonding layers 33 may contain sintered metal particles.

As shown in FIG. 15, the semiconductor device B may further include a second conductive bonding layer 34. The second conductive bonding layer 34 may be interposed between the second obverse surface 122A of the second conductive layer 122 and the second bond portion 314. The second conductive bonding layer 34 may electrically bond the second obverse surface 122A and the second bond portion 314. The second conductive bonding layer 34 may be solder, for example. Alternatively, the second conductive bonding layer 34 may contain sintered metal particles.

As shown in FIGS. 10 and 17, the second conductive member 32 may be electrically bonded to the second electrodes 212 of the second elements 21B and the covered portion 15A of the third power terminal 15. Thus, the second electrodes 212 of the second elements 21B may be electrically connected to the third power terminal 15. The composition of the second conductive member 32 may include copper. The second conductive member 32 may be a metal clip. As shown in FIG. 10, the second conductive member 32 may have a pair of main bodies 321, a plurality of third bond portions 322, a plurality of third connecting portions 323, a pair of fourth bond portions 324, a pair of fourth connecting portions 325, a plurality of intermediate portions 326, and a plurality of cross beam portions 327.

As shown in FIG. 10, the pair of main bodies 321 may be spaced apart from each other in the third direction y. The pair of main bodies 321 may extend in the second direction x. As shown in FIG. 14, the pair of main bodies 321 may be disposed in parallel to the first obverse surface 121A of the first conductive layer 121 and the second obverse surface 122A of the second conductive layer 122. The pair of main bodies 321 may be located farther from the first obverse surface 121A and the second obverse surface 122A than the main body 311 of the first conductive member 31.

As shown in FIG. 10, the intermediate portions 326 may be spaced apart from each other in the third direction y and located between the pair of main bodies 321 in the third direction y. The intermediate portions 326 may extend in the second direction x. The dimension of each intermediate portion 326 in the second direction x may be smaller than the dimension of each main body 321 in the second direction x.

As shown in FIG. 17, the third bond portions 322 may be bonded to the second electrodes 212 of the respective second elements 21B. Each of the third bond portions 322 may face the second electrode 212 of one of the second elements 21B.

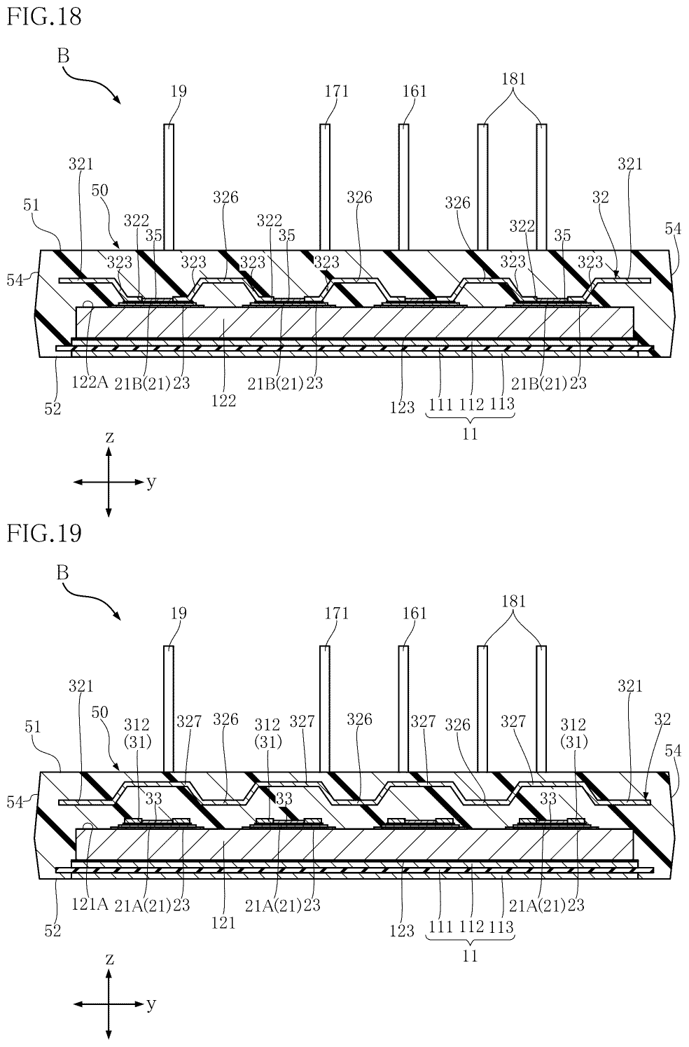

As shown in FIGS. 10 and 18, the third connecting portions 323 are connected to the respective sides of the third bond portions 322 in the third direction y. Each of the third connecting portions 323 may also be connected to one of the main bodies 321 and the intermediate portions 326. As viewed in the second direction x, each of the third connecting portions 323 may be inclined to be farther away from the second obverse surface 122A of the second conductive layer 122 as proceeding from one of the third bond portions 322 toward one of the main bodies 321 and the intermediate portions 326.

As shown in FIGS. 10 and 14, the pair of fourth bond portions 324 may be bonded to the covered portion 15A of the third power terminal 15. The pair of fourth bond portions 324 may face the covered portion 15A.

As shown in FIGS. 10 and 14, the pair of fourth connecting portions 325 may be connected to the pair of main bodies 321 and the pair of fourth bond portions 324. As viewed in the third direction y, the pair of fourth connecting portions 325 may be inclined to be farther away from the first obverse surface 121A of the first conductive layer 121 as proceeding from the pair of fourth bond portions 324 toward the pair of main bodies 321.

As shown in FIGS. 10 and 19, the cross beam portions 327 may be aligned in the third direction y. As viewed in the first direction z, each of the cross beam portions 327 may include a region overlapping with one of the first bond portions 312 of the first conductive member 31. Each cross beam portion 327 located between other beam portions 327 in the third direction y may be connected on both sides in the third direction y to intermediate portions 326. Each of the remaining two cross beam portions 327 may be connected on one side in the third direction y to one of the pair of main bodies 321 and on the other side in the third direction y to one of the intermediate portions 326. As viewed in the second direction x, each of the cross beam portions 327 protrudes to the side that the first obverse surface 121A of the first conductive layer 121 faces in the first direction z.

As shown in FIGS. 15, 17, and 18, the semiconductor device B may further include third conductive bonding layers 35. The third conductive bonding layers 35 may be interposed between the second electrodes 212 of the second elements 21B and the third bond portions 322. The third conductive bonding layers 35 may electrically bond the second electrodes 212 of the second elements 21B and the third bond portions 322. The third conductive bonding layers 35 may be solder, for example. Alternatively, the third conductive bonding layers 35 may contain sintered metal particles.

As shown in FIG. 14, the semiconductor device B may further include fourth conductive bonding layers 36. The fourth conductive bonding layers 36 may be interposed between the covered portion 15A of the third power terminal 15 and the pair of fourth bond portions 324. The fourth conductive bonding layers 36 may electrically bond the covered portion 15A and the pair of fourth bond portions 324. The fourth conductive bonding layers 36 may be solder, for example. Alternatively, the fourth conductive bonding layers 36 may contain sintered metal particles.

As shown in FIGS. 14, 15, 18, and 19, the sealing resin 50 may cover the first conductive layer 121, the second conductive layer 122, the semiconductor elements 21, the first conductive member 31, and the second conductive member 32. The sealing resin 50 may further cover a portion of each of the substrate 11, the first power terminal 13, the second power terminal 14, and the third power terminal 15. The sealing resin 50 may be electrically insulating. The sealing resin 50 may be made of a material containing black epoxy resin, for example. As shown in FIGS. 8, and 12 to 15, the sealing resin 50 may have a top surface 51, a bottom surface 52, a pair of first side surfaces 53, a pair of second side surfaces 54, and a pair of recesses 55.

As shown in FIGS. 14 and 15, the top surface 51 faces the same side as the first obverse surface 121A of the first conductive layer 121 in the first direction z. As shown in FIGS. 14 and 15, the bottom surface 52 faces away from the top surface 51 in the first direction z. As shown in FIG. 13, the heat dissipation layer 113 of the substrate 11 may be exposed at the bottom surface 52.

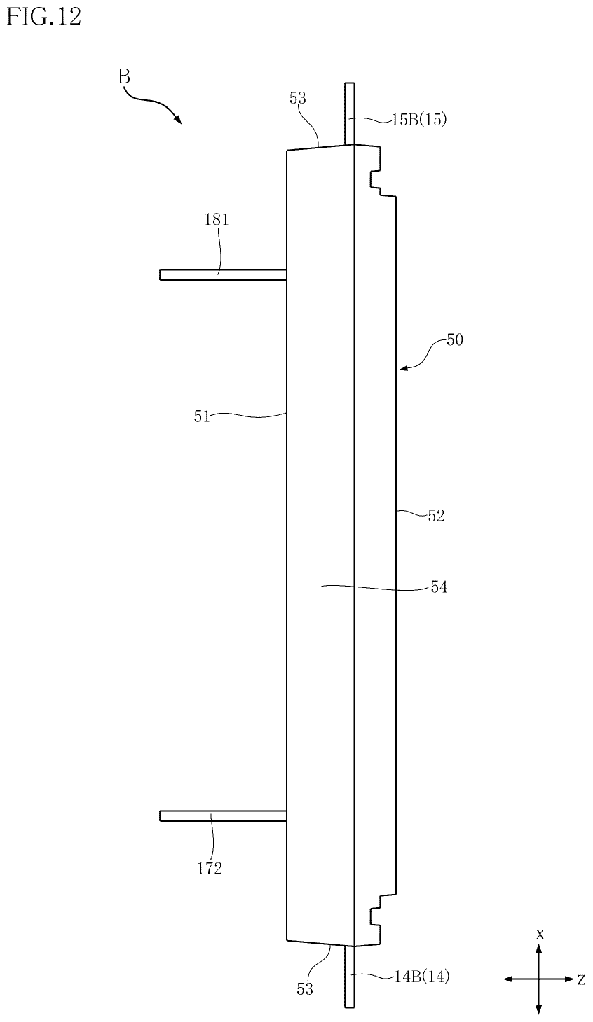

As shown in FIGS. 8 and 12, the pair of first side surfaces 53 may be spaced apart from each other in the second direction x. The first side surfaces 53 face in the second direction x and extend in the third direction y. The first side surfaces 53 may be connected to the top surface 51. The exposed portion 13B of the first power terminal 13 and the exposed portion 15B of the third power terminal 15 may be exposed from one of the pair of first side surfaces 53. The exposed portion 14B of the second power terminal 14 may be exposed from the other one of the pair of first side surfaces 53.

As shown in FIGS. 8 and 13, the pair of second side surfaces 54 may be spaced apart from each other in the third direction y. The pair of second side surfaces 54 face away from each other in the third direction y and extend in the second direction x. The pair of second side surfaces 54 may be connected to the top surface 51 and the bottom surface 52.

As shown in FIGS. 8 and 13, the pair of recesses 55 may be recessed in the second direction x from the first side surface 53 from which the exposed portion 13B of the first power terminal 13 and the exposed portion 15B of the third power terminal 15 are exposed. The pair of recesses 55 extend from the top surface 51 to the bottom surface 52 in the first direction z. The pair of recesses 55 flank the first power terminal 13 in the third direction y.

Next, the bonding layer 71, the covering layer 72, the frame 73, and the heat dissipation member 80 in the semiconductor module A10 will be described with reference to FIGS. 1 to 7.

The heat dissipation member 80 may be provided to cool the semiconductor device B. The heat dissipation member 80 may contain metal. The heat dissipation member 80 may be made of a material containing aluminum, for example. The substrate 11 may be located on one side of the heat dissipation member 80 in the first direction z and bonded to the heat dissipation member 80. The bottom surface 52 of the sealing resin 50 may face the heat dissipation member 80.

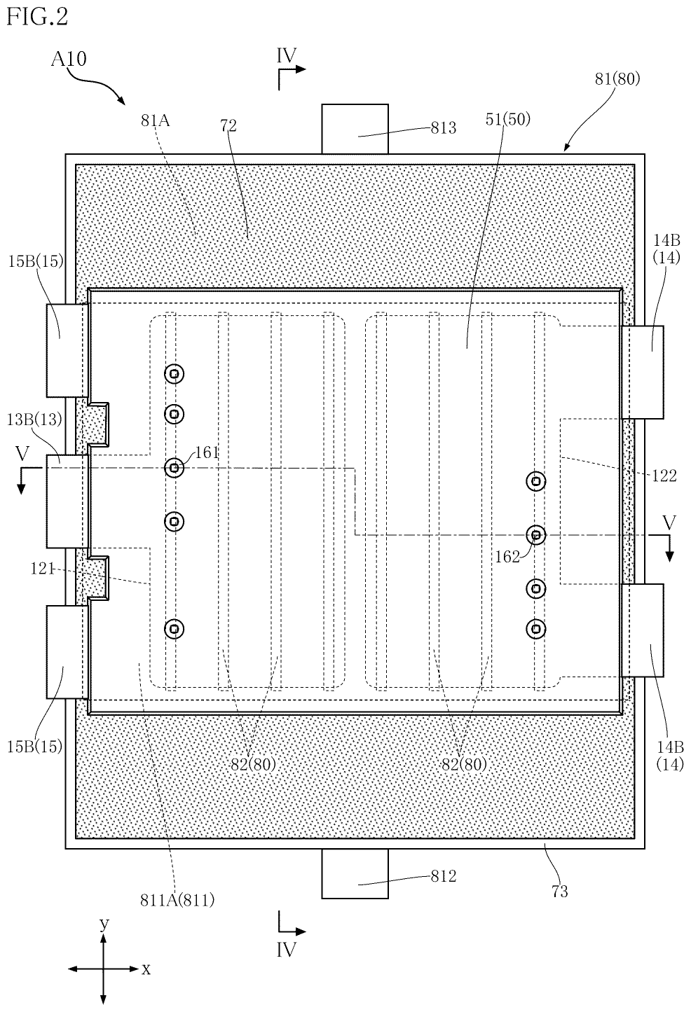

As shown in FIGS. 2 to 5, the heat dissipation member 80 may have a housing 81 and a heat dissipator 82. The housing 81 may have a hollow portion 811, an inlet 812, and an outlet 813. The hollow portion 811 may be located inside the housing 81. The inlet 812 and the outlet 813 may be connected to the hollow portion 811. The inlet 812 and the outlet 813 may be located opposite to each other with respect to the hollow portion 811 in the third direction y. The heat dissipation member 80 may be configured such that a coolant flows from the inlet 812 to the outlet 813 via the hollow portion 811.

As shown in FIGS. 2 to 5, the housing 81 may have a mounting surface 81A facing in the first direction z. The mounting surface 81A may face the heat dissipation layer 113 of the substrate 11.

As shown in FIGS. 2 to 5, the hollow portion 811 of the housing 81 may include a narrow section 811A. The narrow section 811A is where the cross-sectional area of the hollow portion 811 is the smallest in the section from the inlet 812 to the outlet 813 in a direction perpendicular to the first direction z.

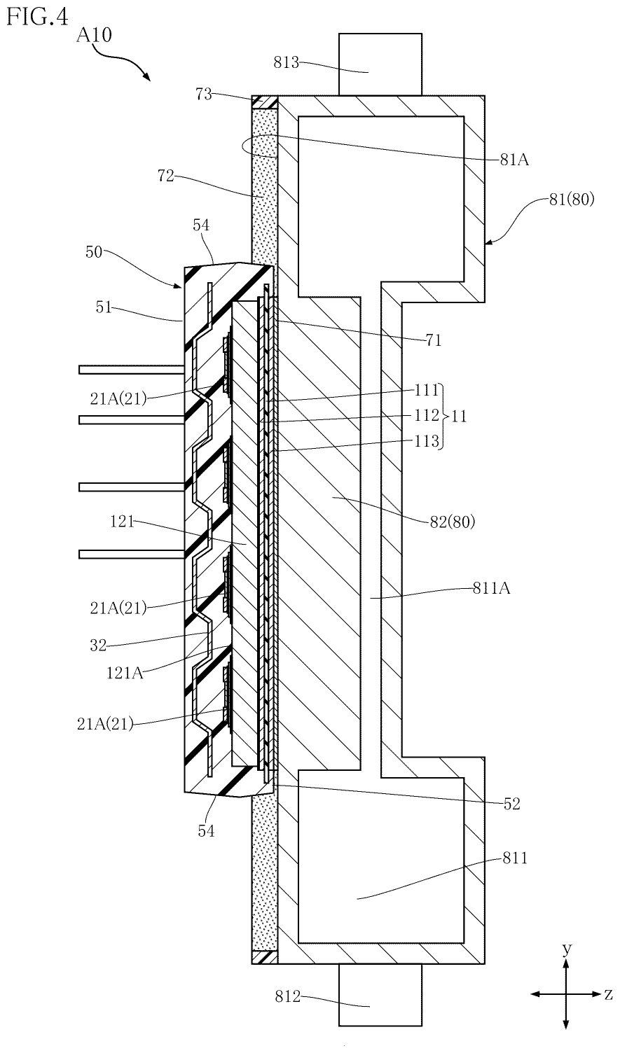

As shown in FIGS. 2 to 5, the heat dissipator 82 may be housed in the narrow section 811A of the hollow portion 811 in the housing 81. The heat dissipator 82 may be connected to the housing 81. As shown in FIGS. 2 to 5, the heat dissipator 82 may be a plurality of fins spaced apart from each other in the second direction x. As shown in FIGS. 2 and 4, the fins may extend in the third direction y. Thus, the fins may extend in a direction perpendicular to the first direction z and along the section from the inlet 812 to the outlet 813.

As shown in FIG. 2, the first conductive layer 121 and the second conductive layer 122 may overlap with the narrow section 811A of the hollow portion 811 in the housing 81. As viewed in the first direction z, the first conductive layer 121 and the second conductive layer 122 may also overlap with the heat dissipator 82.

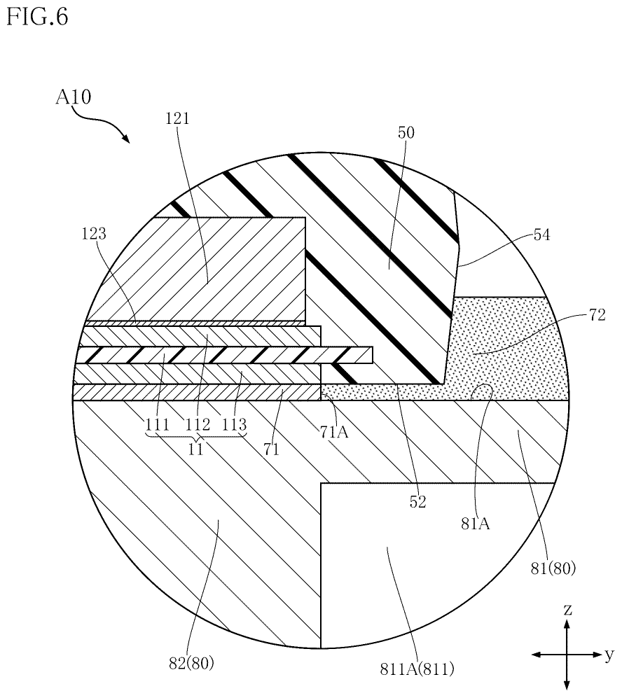

As shown in FIGS. 4 to 6, the bonding layer 71 may bond the mounting surface 81A of the housing 81 and the heat dissipation layer 113 of the substrate 11. The bonding layer 71 may contain metal. The bonding layer 71 may be formed from sintered metal particles containing silver, for example, or may be formed by solder bonding or solid-phase diffusion bonding. As shown in FIG. 6, the bonding layer 71 may have an end surface 71A facing in a direction perpendicular to the first direction z.

As shown in FIGS. 1 to 5, the frame 73 may stand from the heat dissipation member 80 toward the first power terminal 13, the second power terminal 14, and the third power terminal 15 in the first direction z. The frame 73 may be an insulator. The frame 73 may contain resin, for example. In the semiconductor module A10, the frame 73 may be bonded to the housing 81 along the periphery of the mounting surface 81A of the housing 81. As viewed in the first direction z, the frame 73 may surround the sealing resin 50 and the covering layer 72. As viewed in a direction perpendicular to the first direction z, the frame 73 may overlap with the pair of first side surfaces 53 of the sealing resin 50 and the pair of second side surfaces 54 of the sealing resin 50.

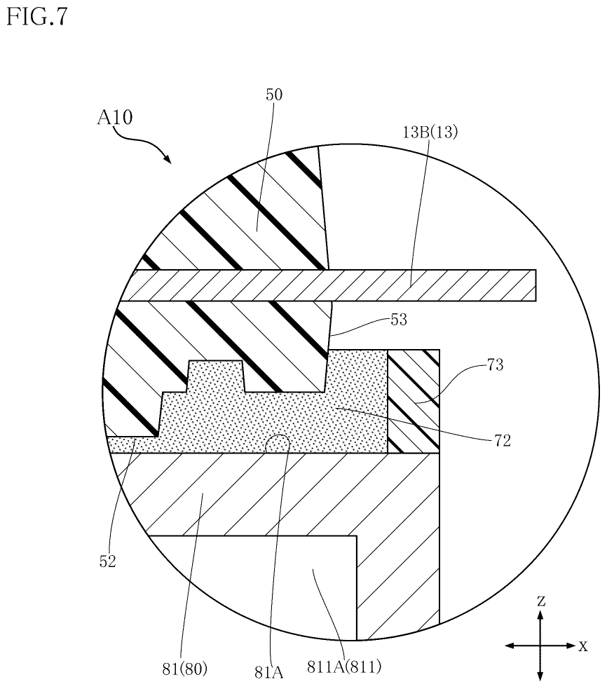

As shown in FIGS. 1, 2, 4, and 5, the covering layer 72 may cover a portion of the heat dissipation member 80. The covering layer 72 may be located on the side of the heat dissipation member 80 where the substrate 11 is located in the first direction z. The covering layer 72 may cover the mounting surface 81A of the housing 81 and the bottom surface 52 of the sealing resin 50, and may be in contact with the pair of first side surfaces 53 of the sealing resin 50 and the pair of second side surfaces 54 of the sealing resin 50. As shown in FIG. 6, the covering layer 72 may be in contact with the end surface 71A of the bonding layer 71. The coefficient of linear expansion of the covering layer 72 may be larger than that of the bonding layer 71. As shown in FIG. 7, the covering layer 72 may be in contact with the frame 73. The dimension of the covering layer 72 in the first direction z may be equal to the dimension of the frame 73 in the first direction z.

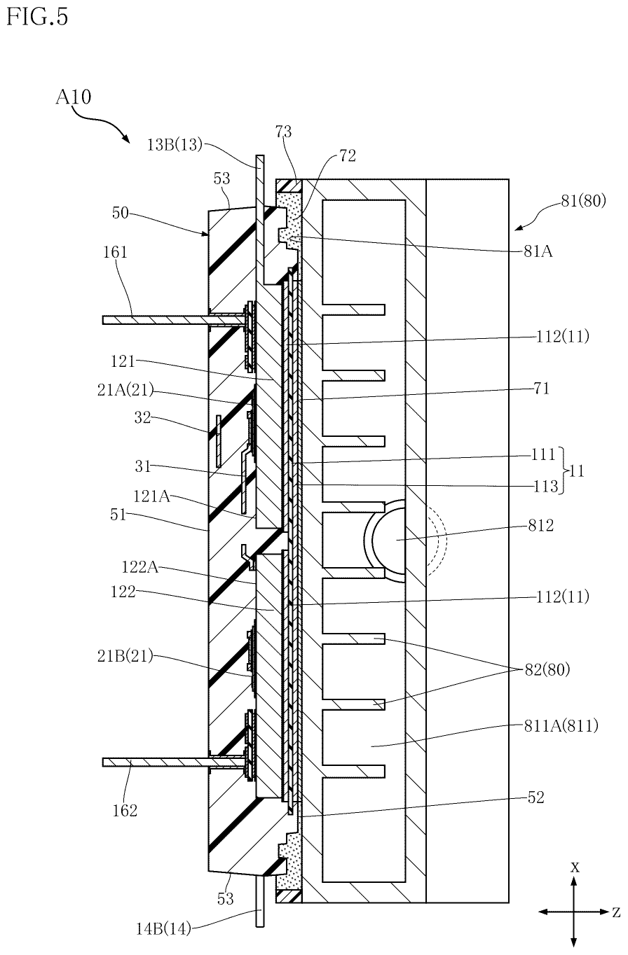

As shown in FIGS. 2, 4, and 5, the covering layer 72 may surround the bonding layer 71 and the sealing resin 50 as viewed in the first direction z. As viewed in the first direction z, each of the first power terminal 13, the second power terminal 14, and the third power terminal 15 may overlap with the heat dissipation member 80 and the covering layer 72. As viewed in FIGS. 4 and 5, the covering layer 72 may be spaced apart from the first power terminal 13, the second power terminal 14, and the third power terminal 15. As viewed in the first direction z, the sealing resin 50 may overlap with the covering layer 72.

The covering layer 72 of the semiconductor module A10 may be formed through the following steps. First, the semiconductor device B is bonded to the mounting surface 81A of the housing 81 via the bonding layer 71. In doing so, the heat dissipation layer 113 of the substrate 11 is bonded to the mounting surface 81A. Next, the frame 73 is bonded to the mounting surface 81A. At this point, the frame 73 is prevented from making contact with the first power terminal 13, the second power terminal 14, and the third power terminal 15. Next, a dispenser or the like is used to pour a melted resin material onto the mounting surface 81A surrounded by the frame 73. The melted resin material is poured so as to cover the pair of first side surfaces 53 of the sealing resin 50 and the pair of second side surfaces 54 of the sealing resin 50. Finally, the resin material is cured to complete the formation of the covering layer 72.

The following describes advantages of the semiconductor module A10.

The semiconductor module A10 may include the heat dissipation member 80, the semiconductor device B bonded to the heat dissipation member 80, and the covering layer 72 that covers a part of the heat dissipation member 80, and that is an insulator. The semiconductor device B may include the substrate 11 located on one side of the heat dissipation member 80 in the first direction z and bonded to the heat dissipation member 80, the first conductive layer 121, the semiconductor elements 21 (the first elements 21A), the sealing resin 50, and the first power terminal 13 that is electrically connected to the first conductive layer 121 and the semiconductor elements 21, and that includes a portion protruding from the sealing resin 50 to the outside in a direction perpendicular to the first direction z. The covering layer 72 may be located on the one side of the heat dissipation member 80 in the first direction z. As viewed in the first direction z, the first power terminal 13 may overlap with the heat dissipation member 80 and the covering layer 72. With this configuration, heat generated from the semiconductor device B can be released from the substrate 11 to the outside via the heat dissipation member 80, and the creepage distance from the first power terminal 13 to the heat dissipation member 80 can be increased by the covering layer 72. Thus, this configuration can increase the cooling efficiency of the semiconductor device B in the semiconductor module A10 while suppressing a decrease in the dielectric strength of the semiconductor device B.

As viewed in the first direction z, the sealing resin 50 may overlap with the covering layer 72. This configuration may further increase the creepage distance from the first power terminal 13 to the heat dissipation member 80. This makes it possible to effectively suppress a decrease in the dielectric strength of the semiconductor device B.

The semiconductor module A10 may further include the bonding layer 71 that bonds the mounting surface 81A of the heat dissipation member 80 and the substrate 11, and that contains metal. The covering layer 72 may be in contact with the bonding layer 71. The bonding layer 71 may be subjected to a thermal strain caused by the heat generated from the semiconductor device B. Thus, the configuration as described above is provided so that the thermal strain concentrated in the bonding layer 71 is reduced by the covering layer 72 and the thermal strain in the bonding layer 71 is suppressed as a result. This makes it possible to reduce cracks created in the bonding layer 71. In this regard, it is preferable that the coefficient of linear expansion of the covering layer 72 be larger than that of the bonding layer 71 in order to effectively suppress the thermal strain in the bonding layer 71.

The sealing resin 50 may have the bottom surface 52 that faces the heat dissipation member 80 in the first direction z. The covering layer 72 may cover the bottom surface 52. This configuration can sufficiently increase the creepage distance from the first power terminal 13 to the bonding layer 71, and can improve the bonding strength between the heat dissipation member 80 and the semiconductor device B.

The sealing resin 50 may have the pair of first side surfaces 53 and the pair of second side surfaces 54 that each face a direction perpendicular to the first direction z. The covering layer 72 may be in contact with the pair of first side surfaces 53 and the pair of second side surfaces 54. This configuration can further increase the creepage distance from the first power terminal 13 to the heat dissipation member 80. In this case, it is possible to increase the creepage distance more effectively by adopting a configuration where the covering layer 72 surrounds the sealing resin 50 as viewed in the first direction z.

The semiconductor module A10 may further include the frame 73 that stands from the heat dissipation member 80 toward the first power terminal 13 in the first direction z, and that is an insulator. As viewed in the first direction z, the frame 73 may surround the covering layer 72. With this configuration, when the covering layer 72 is formed, excessive spreading of a melted resin material can be prevented by the frame 73. In addition, the dimension of the covering layer 72 in the first direction z can be easily adjusted by the frame 73.

The dimension of each of the first conductive layer 121 and the second conductive layer 122 in the first direction z may be greater than that of the substrate 11 in the first direction z. This configuration allows the first conductive layer 121 and the second conductive layer 122 to easily diffuse heat in a direction perpendicular to the first direction z. This makes it possible to reduce the thermal resistance of each of the first conductive layer 121 and the second conductive layer 122 in the first direction z.

In the semiconductor module A10, the heat dissipation member 80 may include the housing 81 having the mounting surface 81A. The housing 81 may have the hollow portion 811 located inside the housing 81, and may also have the inlet 812 and the outlet 813 that are connected to the hollow portion 811. As viewed in the first direction z, the first conductive layer 121 may overlap with the hollow portion 811. This configuration allows a coolant to flow into the hollow portion 811, thereby improving the cooling efficiency of the semiconductor device B.

The hollow portion 811 of the housing 81 may include the narrow section 811A whose cross-sectional area is the smallest in the section from the inlet 812 to the outlet 813 in a direction perpendicular to the first direction z. As viewed in the first direction z, the first conductive layer 121 may overlap with the narrow section 811A. This configuration can increase the flow velocity of the coolant in the narrow section 811A, thereby further improving the cooling efficiency of the semiconductor device B.

The heat dissipation member 80 may have the heat dissipator 82 housed in the narrow section 811A of the housing 81 and connected to the housing 81. As viewed in the first direction z, the first conductive layer 121 and the second conductive layer 122 may overlap with the heat dissipator 82. This configuration can increase the contact area of the heat dissipation member 80 with respect to the coolant, thereby further improving the cooling efficiency of the semiconductor device B.

The heat dissipator 82 may include the plurality of fins. The fins may extend in a direction perpendicular to the first direction z and along the section from the inlet 812 to the outlet 813. This configuration can prevent blocking of the flow of the coolant in the narrow section 811A of the heat dissipation member 80.

### Second Embodiment

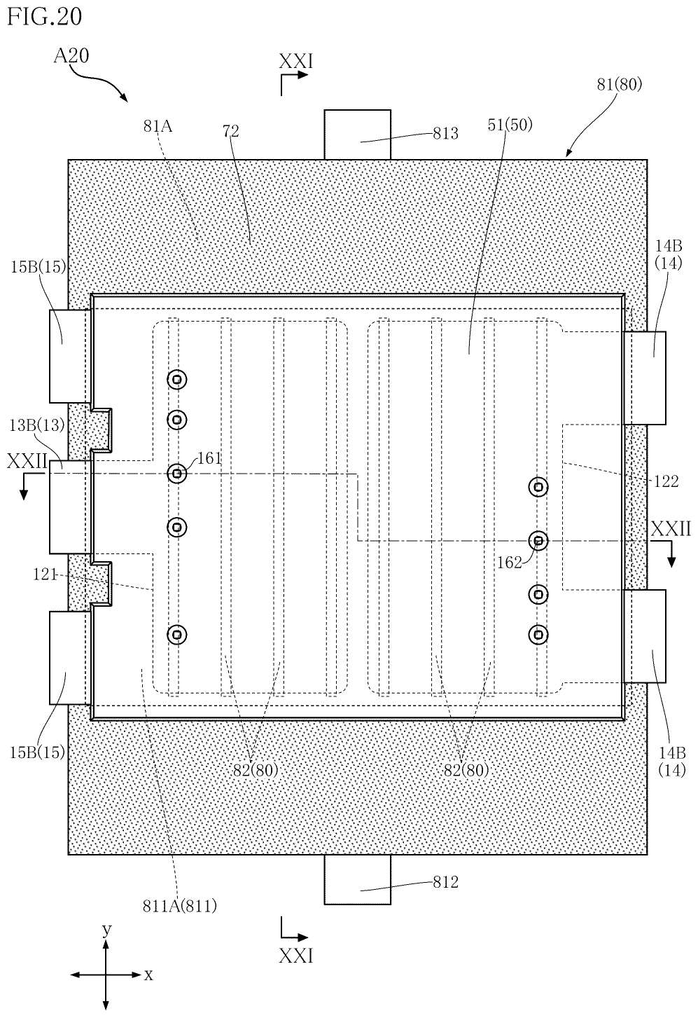

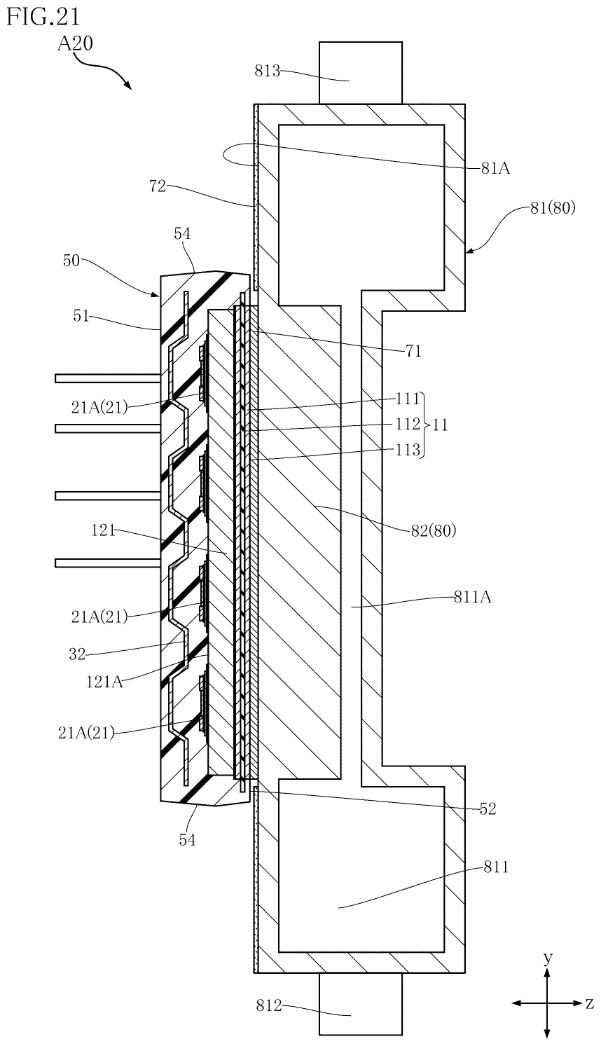

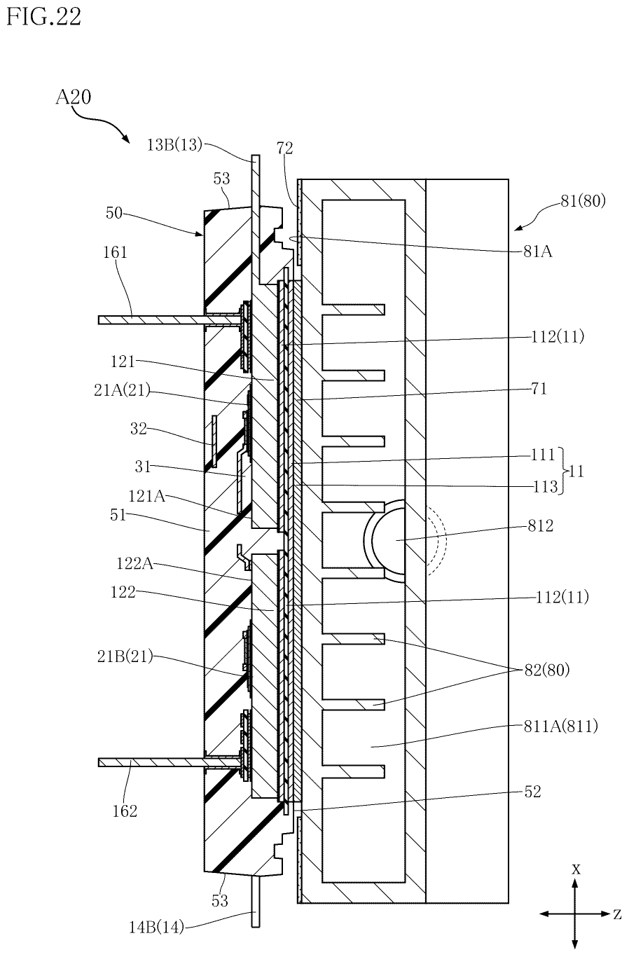

With reference to FIGS. 20 to 23, a semiconductor module A20 according to a second embodiment of the present disclosure will be described. In these figures, elements that are the same as or similar to those of the semiconductor module A10 described above are denoted by the same reference signs and the descriptions thereof are omitted.

The semiconductor module A20 is different from the semiconductor module A10 in not including the frame 73 and in the configuration of the covering layer 72.

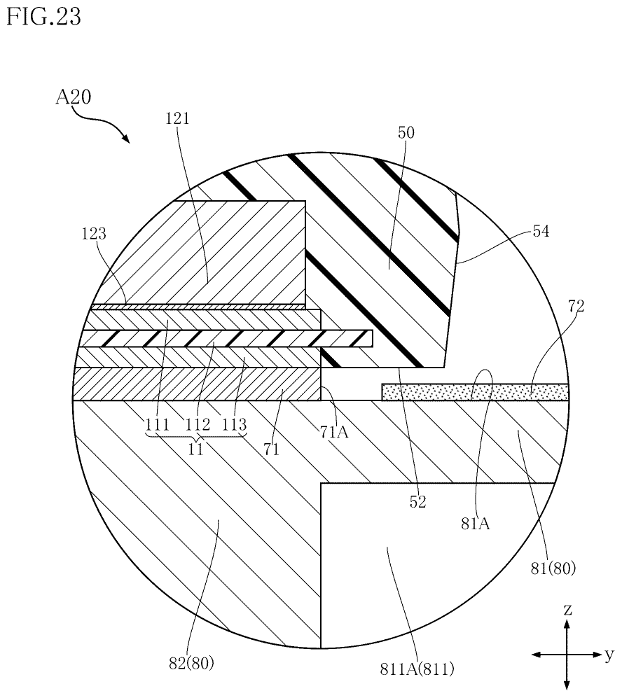

As shown in FIGS. 20 to 22, the covering layer 72 may reach the entire periphery of the mounting surface 81A of the housing 81. The covering layer 72 may be made of a resin sheet or a material containing ceramics. The covering layer 72 may be spaced apart from the pair of first side surfaces 53 of the sealing resin 50 and the pair of second side surfaces 54 of the sealing resin 50. As viewed in the first direction z, the sealing resin 50 may overlap with the covering layer 72. As viewed in the first direction z, the covering layer 72 may surround the bonding layer 71 and the sealing resin 50. As shown in FIG. 23, the covering layer 72 may also be spaced apart from the end surface 71A of the bonding layer 71 and the bottom surface 52 of the sealing resin 50. The dimension of the covering layer 72 in the first direction z may be smaller than the dimension of the bonding layer 71 in the first direction z.

The following describes advantages of the semiconductor module A20.

The semiconductor module A20 may include the heat dissipation member 80, the semiconductor device B bonded to the heat dissipation member 80, and the covering layer 72 that covers a part of the heat dissipation member 80, and that is an insulator. The semiconductor device B may include the substrate 11 located on one side of the heat dissipation member 80 in the first direction z and bonded to the heat dissipation member 80, the first conductive layer 121, the semiconductor elements 21 (the first elements 21A), the sealing resin 50, and the first power terminal 13 that is electrically connected to the first conductive layer 121 and the semiconductor elements 21, and that includes a portion protruding from the sealing resin 50 to the outside in a direction perpendicular to the first direction z. The covering layer 72 may be located on the one side of the heat dissipation member 80 in the first direction z. As viewed in the first direction z, the first power terminal 13 may overlap with the heat dissipation member 80 and the covering layer 72. Thus, this configuration can increase the cooling efficiency of the semiconductor device B in the semiconductor module A20 while suppressing a decrease in the dielectric strength of the semiconductor device B. In addition, the semiconductor module A20 has configurations common to the semiconductor module A10, thereby achieving the same advantages as the semiconductor module A10.

### Third Embodiment

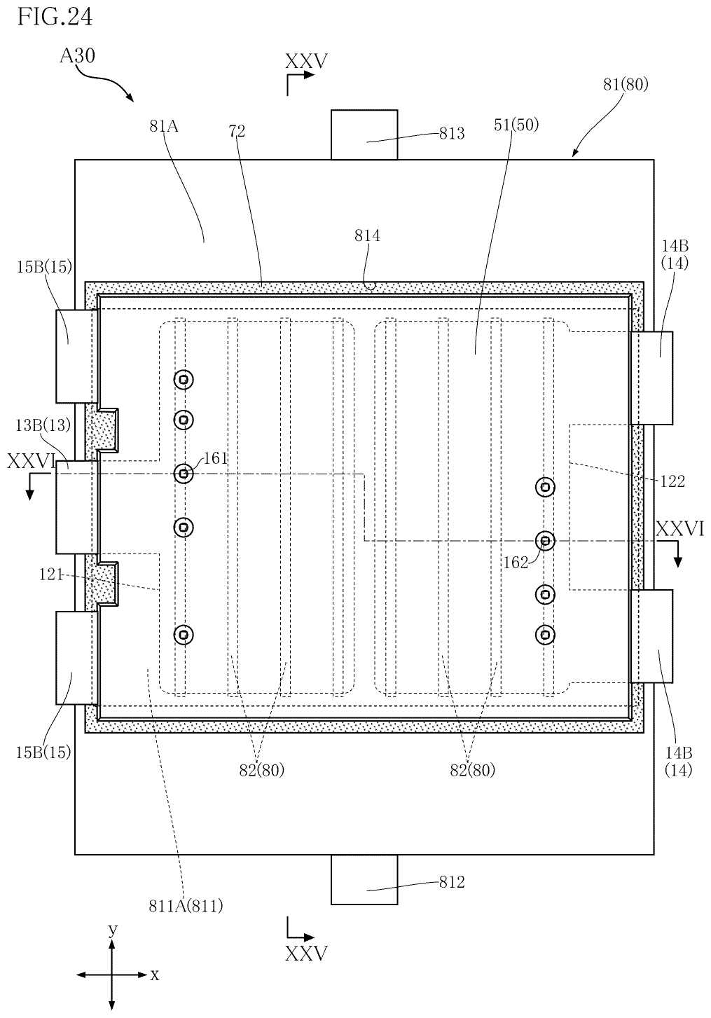

With reference to FIGS. 24 to 27, a semiconductor module A30 according to a third embodiment of the present disclosure will be described. In these figures, elements that are the same as or similar to those of the semiconductor module A10 described above are denoted by the same reference signs and the descriptions thereof are omitted.

The semiconductor module A30 is different from the semiconductor module A10 in not including the frame 73 and in the configurations of the covering layer 72 and the heat dissipation member 80.

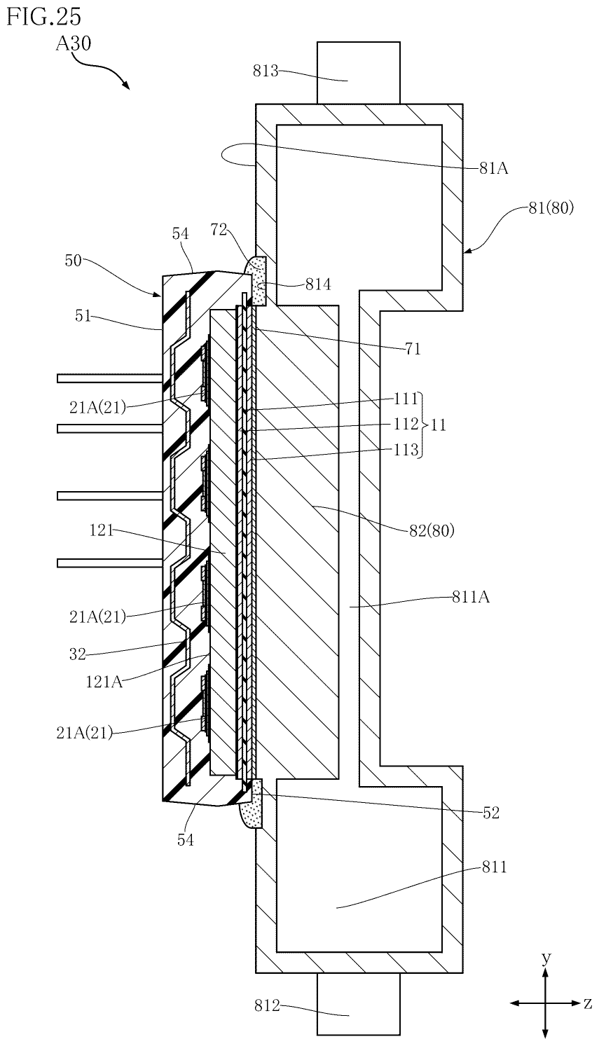

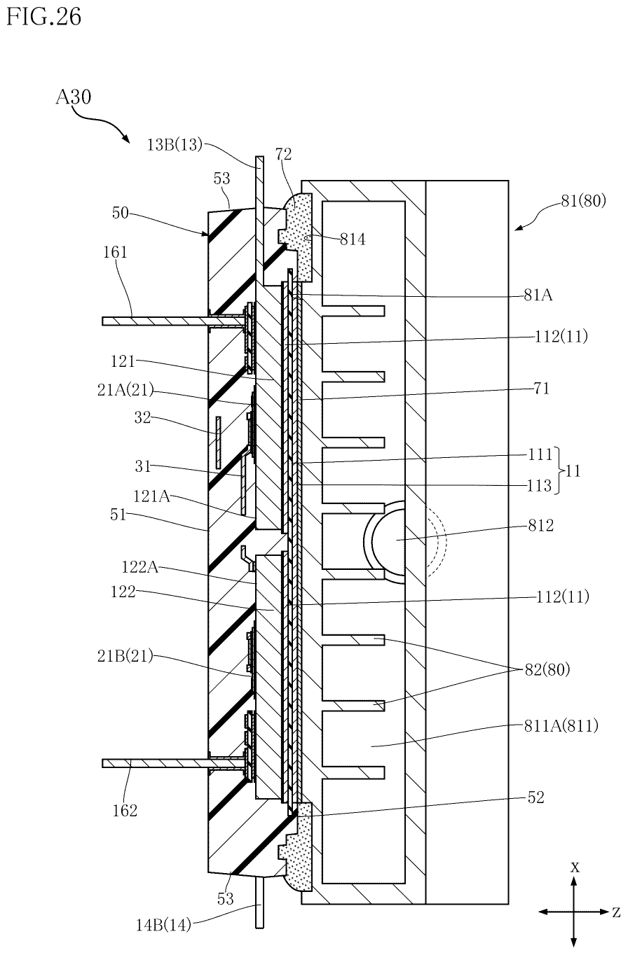

As shown in FIGS. 25 and 26, the housing 81 may have a groove 814 that is located outside the bonding layer 71 as viewed in the first direction z, and that is recessed from the mounting surface 81A of the housing 81. As viewed in the first direction z, the groove 814 may surround the bonding layer 71 and the sealing resin 50. At least a part of the covering layer 72 may be accommodated in the groove 814. As viewed in the first direction z, the first power terminal 13, the second power terminal 14, the third power terminal 15, and the sealing resin 50 may overlap with the groove 814. The mounting surface 81A may include an area not covered with the covering layer 72 and exposed to the outside.

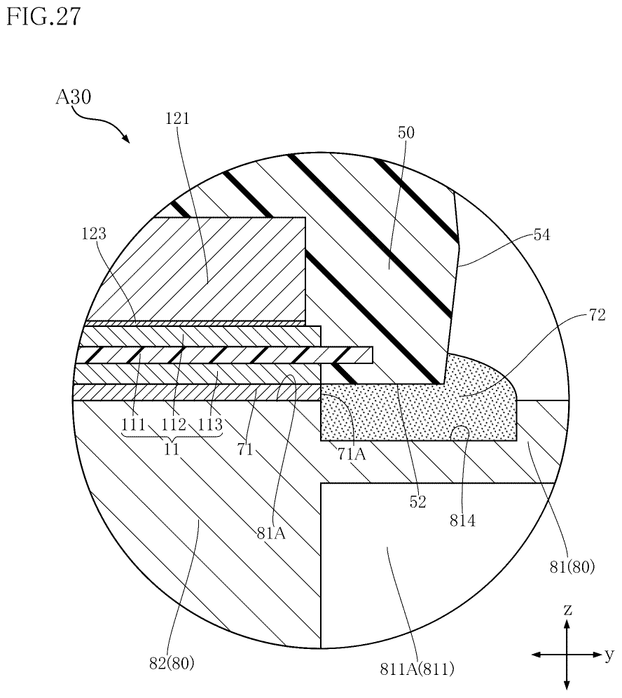

As shown in FIGS. 24 to 26, the covering layer 72 may cover the bottom surface 52 of the sealing resin 50, and may be in contact with the pair of first side surfaces 53 of the sealing resin 50 and the pair of second side surfaces 54 of the sealing resin 50. As shown in FIG. 27, the covering layer 72 may be in contact with the end surface 71A of the bonding layer 71. A part of the covering layer 72 may bulge in the first direction z and spread out of the groove 814 of the housing 81. The covering layer 72 may be formed by first bonding the semiconductor device B to the mounting surface 81A of the housing 81 via the bonding layer 71 and then pouring a melted resin material into the groove 814 of the housing 81 by using a dispenser or the like.

The following describes advantages of the semiconductor module A30.

The semiconductor module A30 may include the heat dissipation member 80, the semiconductor device B bonded to the heat dissipation member 80, and the covering layer 72 that covers a part of the heat dissipation member 80, and that is an insulator. The semiconductor device B may include the substrate 11 located on one side of the heat dissipation member 80 in the first direction z and bonded to the heat dissipation member 80, the first conductive layer 121, the semiconductor elements 21 (the first elements 21A), the sealing resin 50, and the first power terminal 13 that is electrically connected to the first conductive layer 121 and the semiconductor elements 21, and that includes a portion protruding from the sealing resin 50 to the outside in a direction perpendicular to the first direction z. The covering layer 72 may be located on the one side of the heat dissipation member 80 in the first direction z. As viewed in the first direction z, the first power terminal 13 may overlap with the heat dissipation member 80 and the covering layer 72. Thus, this configuration can increase the cooling efficiency of the semiconductor device B in the semiconductor module A30 while suppressing a decrease in the dielectric strength of the semiconductor device B. In addition, the semiconductor module A30 has configurations common to the semiconductor module A10, thereby achieving the same advantages as the semiconductor module A10.

The heat dissipation member 80 may have the groove 814 that is located outside the bonding layer 71 as viewed in the first direction z, and that is recessed from the mounting surface 81A of the housing 81. At least a part of the covering layer 72 may be accommodated in the groove 814. With this configuration, the covering layer 72 may be formed from a melted resin material even without the frame 73.

A part of the covering layer 72 may bulge in the first direction z and spread out of the groove 814. As such, the covering layer 72 may be configured to cover the bottom surface 52 of the sealing resin 50, and to be in contact with the pair of first side surfaces 53 of the sealing resin 50 and the pair of second side surfaces 54 of the sealing resin 50. This makes it possible to suppress a decrease in the dielectric strength of the semiconductor device B, and to reduce cracks in the bonding layer 71 due to the heat generated from the semiconductor device B.

### Fourth Embodiment

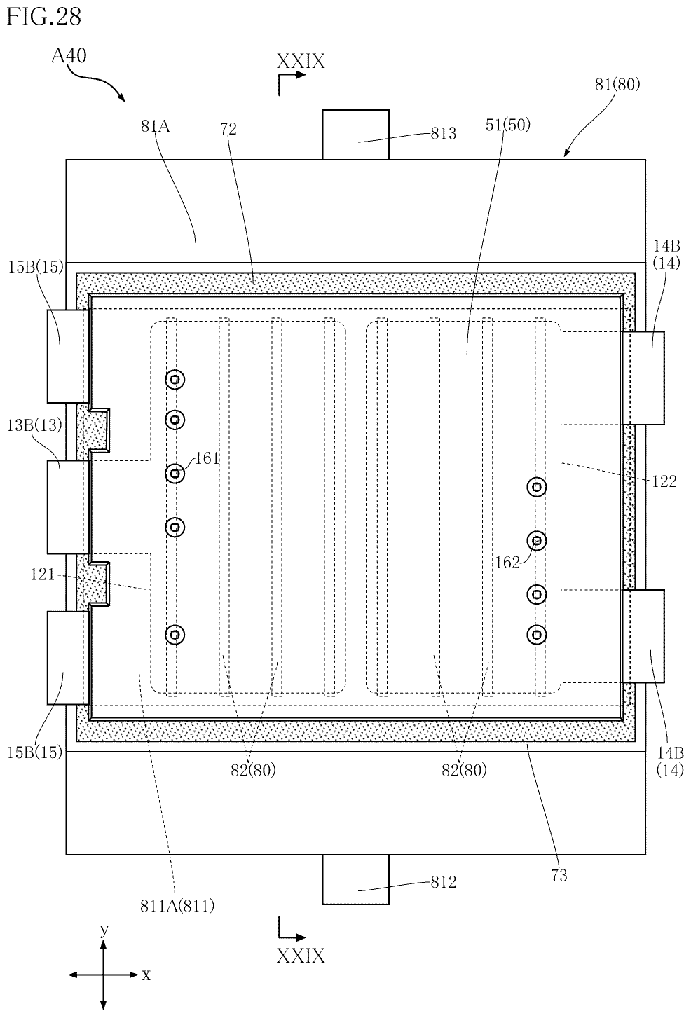

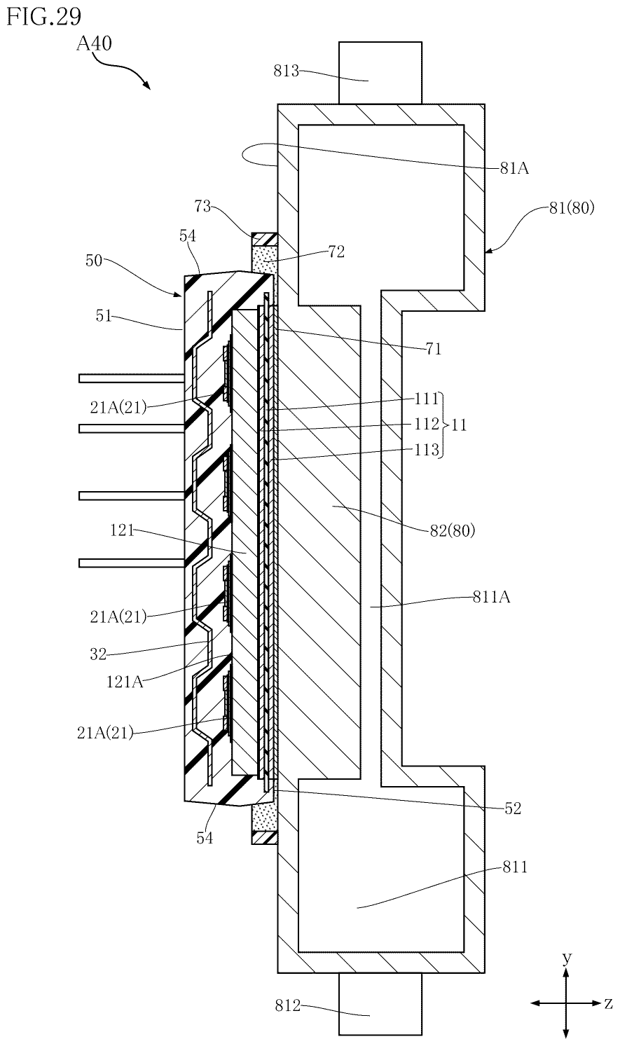

With reference to FIGS. 28 and 29, a semiconductor module A40 according to a fourth embodiment of the present disclosure will be described. In these figures, elements that are the same as or similar to those of the semiconductor module A10 described above are denoted by the same reference signs and the descriptions thereof are omitted.

The semiconductor module A40 is different from the semiconductor module A10 in the configurations of the covering layer 72 and the frame 73.

As shown in FIG. 28, as viewed in the first direction z, the area of the covering layer 72 may be smaller than the area of the covering layer 72 of the semiconductor module A10. In correspondence with the shape of the covering layer 72, the extension of the frame 73 may be shorter than the extension of the frame 73 of the semiconductor module A10. As shown in FIGS. 28 and 29, the mounting surface 81A of the housing 81 has an area that does not overlap with any of the first power terminal 13, the second power terminal 14, and the third power terminal 15 of the semiconductor device B as viewed in the first direction z, and this area may be exposed to the outside. In this way, as can be seen in the semiconductor module A40, the cover range of the covering layer 72 covering the mounting surface 81A can be freely set as long as the first power terminal 13 overlaps with the heat dissipation member 80 and the covering layer 72 as viewed in the first direction z.

The following describes advantages of the semiconductor module A40.

The semiconductor module A40 may include the heat dissipation member 80, the semiconductor device B bonded to the heat dissipation member 80, and the covering layer 72 that covers a part of the heat dissipation member 80, and that is an insulator. The semiconductor device B may include the substrate 11 located on one side of the heat dissipation member 80 in the first direction z and bonded to the heat dissipation member 80, the first conductive layer 121, the semiconductor elements 21 (the first elements 21A), the sealing resin 50, and the first power terminal 13 that is electrically connected to the first conductive layer 121 and the semiconductor elements 21, and that includes a portion protruding from the sealing resin 50 to the outside in a direction perpendicular to the first direction z. The covering layer 72 may be located on the one side of the heat dissipation member 80 in the first direction z. As viewed in the first direction z, the first power terminal 13 may overlap with the heat dissipation member 80 and the covering layer 72. Thus, this configuration can increase the cooling efficiency of the semiconductor device B in the semiconductor module A40 while suppressing a decrease in the dielectric strength of the semiconductor device B. In addition, the semiconductor module A40 has configurations common to the semiconductor module A10, thereby achieving the same advantages as the semiconductor module A10.

### Fifth Embodiment

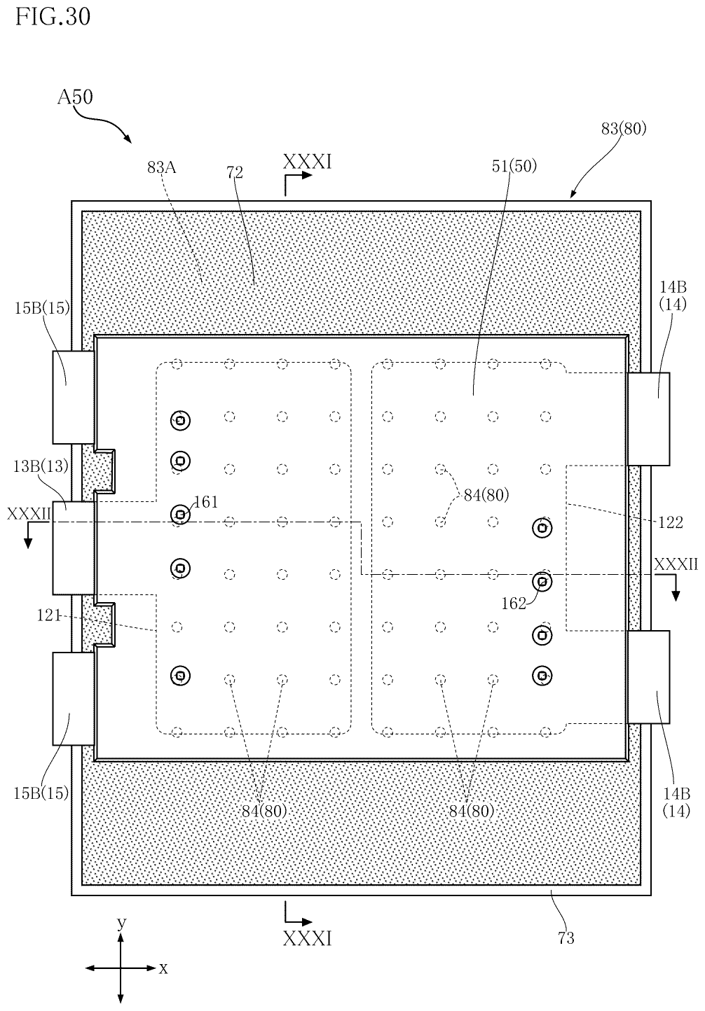

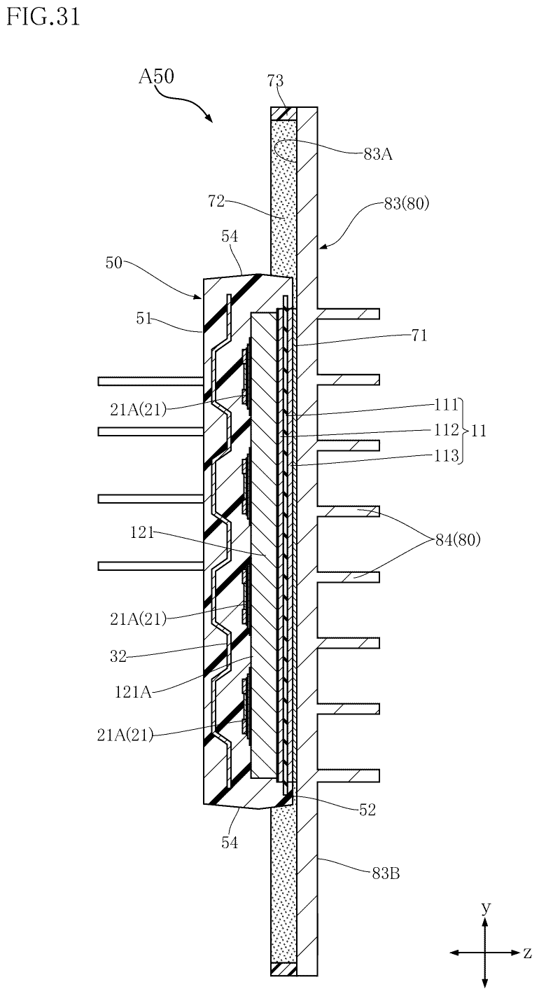

With reference to FIGS. 30 to 32, a semiconductor module A50 according to a fifth embodiment of the present disclosure will be described. In these figures, elements that are the same as or similar to those of the semiconductor module A10 described above are denoted by the same reference signs and the descriptions thereof are omitted.

The semiconductor module A50 is different from the semiconductor module A10 in the configuration of the heat dissipation member 80.

As shown in FIGS. 30 to 32, the heat dissipation member 80 may have a base 83 and a heat dissipator 84, instead of the housing 81 and the heat dissipator 82. The base 83 may have the shape of a flat plate. The base 83 may have a mounting surface 83A and a reverse surface 83B. The mounting surface 83A and the reverse surface 83B may face away from each other in the first direction z. The mounting surface 83A may face the heat dissipation layer 113 of the substrate 11. The bonding layer 71 may be in contact with the mounting surface 83A. The covering layer 72 may cover the mounting surface 83A. The frame 73 may be bonded to the base 83 along the periphery of the mounting surface 83A.

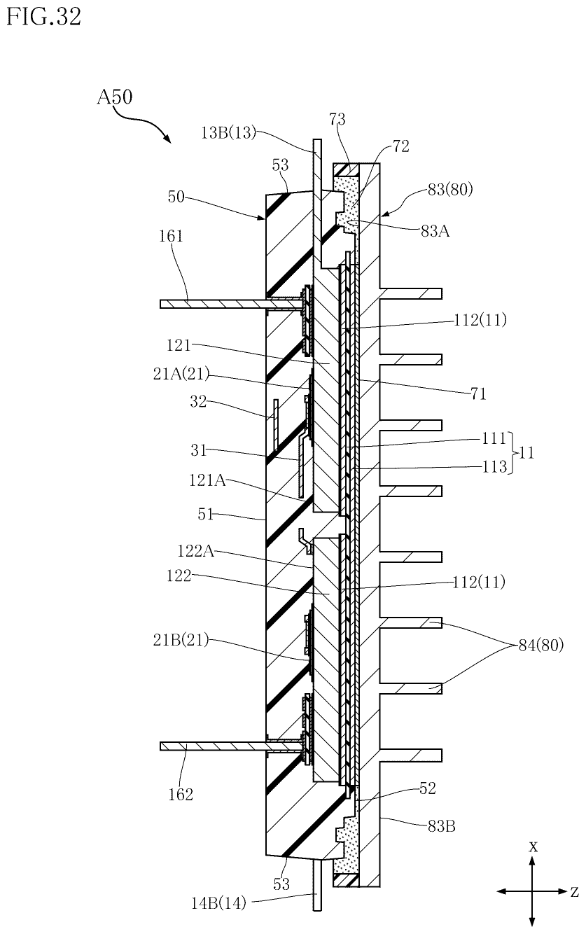

As shown in FIGS. 31 and 32, the heat dissipator 84 may protrude from the reverse surface 83B of the base 83 in the first direction z. The heat dissipator 84 may be located opposite to the substrate 11 with respect to the base 83 in the first direction z. The heat dissipator 84 may be exposed to the outside. The heat dissipator 84 may comprise a plurality of pins spaced apart from each other in a direction perpendicular to the first direction z. As shown in FIG. 30, the heat dissipator 84 may overlap with the first conductive layer 121 and the second conductive layer 122 as viewed in the first direction z.

The following describes advantages of the semiconductor module A50.

The semiconductor module A50 may include the heat dissipation member 80, the semiconductor device B bonded to the heat dissipation member 80, and the covering layer 72 that covers a part of the heat dissipation member 80, and that is an insulator. The semiconductor device B may include the substrate 11 located on one side of the heat dissipation member 80 in the first direction z and bonded to the heat dissipation member 80, the first conductive layer 121, the semiconductor elements 21 (the first elements 21A), the sealing resin 50, and the first power terminal 13 that is electrically connected to the first conductive layer 121 and the semiconductor elements 21, and that includes a portion protruding from the sealing resin 50 to the outside in a direction perpendicular to the first direction z. The covering layer 72 may be located on the one side of the heat dissipation member 80 in the first direction z. As viewed in the first direction z, the first power terminal 13 may overlap with the heat dissipation member 80 and the covering layer 72. Thus, this configuration can increase the cooling efficiency of the semiconductor device B in the semiconductor module A50 while suppressing a decrease in the dielectric strength of the semiconductor device B. In addition, the semiconductor module A50 has configurations common to the semiconductor module A10, thereby achieving the same advantages as the semiconductor module A10.

The semiconductor module A50 may include the base 83 having the mounting surface 83A, and the heat dissipator 84 protruding from the base 83 in the first direction z. The heat dissipator 84 may be exposed to the outside. As viewed in the first direction z, the first conductive layer 121 and the second conductive layer 122 may overlap with the heat dissipator 84. This configuration further increases the surface area of the heat dissipation member 80, thereby improving the cooling efficiency of the semiconductor device B.

The present disclosure is not limited to the above embodiments. Various design changes can be made to the specific configurations of the respective elements of the present disclosure. The present disclosure includes the embodiments described in the following clauses.

Clause 1.

A semiconductor module comprising:
a heat dissipation member;
a semiconductor device bonded to the heat dissipation member; and
a covering layer that covers a part of the heat dissipation member, and that is an insulator,
wherein the semiconductor device includes a substrate located on one side of the heat dissipation member in a first direction and bonded to the heat dissipation member, a conductive layer located opposite to the heat dissipation member with respect to the substrate and bonded to the substrate, a semiconductor element bonded to the conductive layer, a sealing resin covering the conductive layer and the semiconductor element, and a power terminal that is electrically connected to the conductive layer and the semiconductor element, and that includes a portion protruding from the sealing resin to an outside in a direction perpendicular to the first direction,
the covering layer is located on the one side of the heat dissipation member in the first direction, and
as viewed in the first direction, the power terminal overlaps with the heat dissipation member and the covering layer.

Clause 2.

The semiconductor module according to clause 1, wherein the covering layer is spaced apart from the power terminal.

Clause 3.

The semiconductor module according to clause 2, wherein the sealing resin overlaps with the covering layer as viewed in the first direction.

Clause 4.

The semiconductor module according to clause 3, wherein the heat dissipation member includes a mounting surface facing the substrate in the first direction, and
the semiconductor module further comprises a bonding layer bonding the mounting surface and the substrate and containing metal.

Clause 5.

The semiconductor module according to clause 4, wherein the covering layer is in contact with the bonding layer.

Clause 6.

The semiconductor module according to clause 5, wherein a coefficient of linear expansion of the covering layer is larger than a coefficient of linear expansion of the bonding layer.

### Clause 7.

The semiconductor module according to clause 5, wherein the sealing resin includes a bottom surface facing the heat dissipation member in the first direction, and
the covering layer covers the bottom surface.

Clause 8.

The semiconductor module according to clause 7, wherein the sealing resin includes a side surface facing in a direction perpendicular to the first direction, and
the covering layer is in contact with the side surface.

Clause 9.

The semiconductor module according to clause 8, wherein the covering layer surrounds the sealing resin as viewed in the first direction.

Clause 10.

The semiconductor module according to clause 9, further comprising a frame that stands from the heat dissipation member toward the power terminal in the first direction, and that is an insulator,
wherein the frame surrounds the covering layer as viewed in the first direction.

Clause 11.

The semiconductor module according to clause 4, wherein the covering layer reaches a periphery of the mounting surface.

Clause 12.

The semiconductor module according to clause 4, wherein the heat dissipation member includes a groove that is located outside the bonding layer as viewed in the first direction, and that is recessed from the mounting surface, and
at least a part of the covering layer is accommodated in the groove.

Clause 13.

The semiconductor module according to clause 12, wherein a part of the covering layer bulges in the first direction and spreads out of the groove.

Clause 14.

The semiconductor module according to any of clauses 4 to 13, wherein the heat dissipation member may include a housing including the mounting surface,
the housing includes a hollow portion located inside the housing, and an inlet and an outlet that are connected to the hollow portion, and
the conductive layer overlaps with the hollow portion as viewed in the first direction.

Clause 15.

The semiconductor module according to clause 14, wherein the hollow portion includes a narrow section whose cross-sectional area is a smallest in a section from the inlet to the outlet in a direction perpendicular to the first direction, and
the conductive layer overlaps with the narrow section as viewed in the first direction.

Clause 16.

The semiconductor module according to clause 15, wherein the heat dissipation member includes a heat dissipator housed in the narrow section and connected to the housing, and the conductive layer overlaps with the heat dissipator as viewed in the first direction.

Clause 17.

The semiconductor module according to any of clauses 4 to 13, wherein the heat dissipation member includes a base including the mounting surface, and a heat dissipator that is located opposite to the substrate with respect to the base, and that protrudes from the base in the first direction,
the heat dissipator is exposed to an outside, and
the conductive layer overlaps with the heat dissipator as viewed in the first direction.

### REFERENCE NUMERALS

A10, A20, A30, A40, A50: Semiconductor module
B: Semiconductor device 11: Substrate
111: Insulating layer 112: Metal layer
113: Heat dissipation layer 121: First conductive layer
121A: First obverse surface 122: Second conductive layer
122A: Second obverse surface 123: Bonding layer
13: First power terminal 13A: Covered portion
13B: Exposed portion 14: Second power terminal
14A: Covered portion 14B: Exposed portion
15: Third power terminal 15A: Covered portion
15B: Exposed portion 161: First signal terminal
162: Second signal terminal 171: Third signal terminal
172: Fourth signal terminal 181: Fifth signal terminal
182: Sixth signal terminal 19: Seventh signal terminal
21: Semiconductor element 21A: First element
21B: Second element 211: First electrode
212: Second electrode 213: Third electrode
214: Fourth electrode 22: Thermistor
23: Conductive bonding layer 31: First conductive member
311: Main body 312: First bond portion
313: First connecting portion 314: Second bond portion
315: Second connecting portion 32: Second conductive member
321: Main body 322: Third bond portion
323: Third connecting portion 324: Fourth bond portion
325: Fourth connecting portion 326: Intermediate portion
327: Cross beam portion 33: First conductive bonding layer
34: Second conductive bonding layer 35: Third conductive bonding layer
36: Fourth conductive bonding layer 41: First wire
42: Second wire 43: Third wire
44: Fourth wire 50: Sealing resin
51: Top surface 52: Bottom surface
53: First side surface 54: Second side surface
55: Recess 60: Control wiring
601: First wiring 602: Second wiring
61: Insulating layer 62: Wiring layer
621: First wiring layer 622: Second wiring layer
623: Third wiring layer 624: Fourth wiring layer
625: Fifth wiring layer 63: Metal layer
64: Sleeve 641: End surface
68: First adhesive layer 69: Second adhesive layer
71: Bonding layer 71A: End surface
72: Covering layer 73: Frame
80: Heat dissipation member 81: Housing
81A: Mounting surface 811: Hollow portion
811A: Narrow section 812: Inlet
813: Outlet 82: Heat dissipator
83: Base 83A: Mounting surface
83B: Reverse surface 84: Heat dissipator
z: First direction x: Second direction
y: Third direction

1. A semiconductor module comprising:
a heat dissipation member;
a semiconductor device bonded to the heat dissipation member; and
a covering layer that covers a part of the heat dissipation member, and that is an insulator,
wherein the semiconductor device includes a substrate located on one side of the heat dissipation member in a first direction and bonded to the heat dissipation member, a conductive layer located opposite to the heat dissipation member with respect to the substrate and bonded to the substrate, a semiconductor element bonded to the conductive layer, a sealing resin covering the conductive layer and the semiconductor element, and a power terminal that is electrically connected to the conductive layer and the semiconductor element, and that includes a portion protruding from the sealing resin to an outside in a direction perpendicular to the first direction,
the covering layer is located on the one side of the heat dissipation member in the first direction, and
as viewed in the first direction, the power terminal overlaps with the heat dissipation member and the covering layer.

2. The semiconductor module according to claim 1, wherein the covering layer is spaced apart from the power terminal.

3. The semiconductor module according to claim 2, wherein the sealing resin overlaps with the covering layer as viewed in the first direction.

4. The semiconductor module according to claim 3, wherein the heat dissipation member includes a mounting surface facing the substrate in the first direction, and
the semiconductor module further comprises a bonding layer bonding the mounting surface and the substrate and containing metal.

5. The semiconductor module according to claim 4, wherein the covering layer is in contact with the bonding layer.

6. The semiconductor module according to claim 5, wherein a coefficient of linear expansion of the covering layer is larger than a coefficient of linear expansion of the bonding layer.

7. The semiconductor module according to claim 5, wherein the sealing resin includes a bottom surface facing the heat dissipation member in the first direction, and
the covering layer covers the bottom surface.

8. The semiconductor module according to claim 7, wherein the sealing resin includes a side surface facing in a direction perpendicular to the first direction, and
the covering layer is in contact with the side surface.

9. The semiconductor module according to claim 8, wherein the covering layer surrounds the sealing resin as viewed in the first direction.

10. The semiconductor module according to claim 9, further comprising a frame that stands from the heat dissipation member toward the power terminal in the first direction, and that is an insulator,
wherein the frame surrounds the covering layer as viewed in the first direction.

11. The semiconductor module according to claim 4, wherein the covering layer reaches a periphery of the mounting surface.

12. The semiconductor module according to claim 4, wherein the heat dissipation member includes a groove that is located outside the bonding layer as viewed in the first direction, and that is recessed from the mounting surface, and
at least a part of the covering layer is accommodated in the groove.

13. The semiconductor module according to claim 12, wherein a part of the covering layer bulges in the first direction and spreads out of the groove.

14. The semiconductor module according to claim 4, wherein the heat dissipation member may include a housing including the mounting surface,
the housing includes a hollow portion located inside the housing, and an inlet and an outlet that are connected to the hollow portion, and
the conductive layer overlaps with the hollow portion as viewed in the first direction.

15. The semiconductor module according to claim 14, wherein the hollow portion includes a narrow section whose cross-sectional area is a smallest in a section from the inlet to the outlet in a direction perpendicular to the first direction, and
the conductive layer overlaps with the narrow section as viewed in the first direction.

16. The semiconductor module according to claim 15, wherein the heat dissipation member includes a heat dissipator housed in the narrow section and connected to the housing, and
the conductive layer overlaps with the heat dissipator as viewed in the first direction.

17. The semiconductor module according to claim 4, wherein the heat dissipation member includes a base including the mounting surface, and a heat dissipator that is located opposite to the substrate with respect to the base, and that protrudes from the base in the first direction,
the heat dissipator is exposed to an outside, and
the conductive layer overlaps with the heat dissipator as viewed in the first direction.
